(19) United States
(12) Patent Application Publication
(10) Pub. No.: US 2026/0143787 A1
(43) Pub. Date: May 21, 2026

(54) CFET STRUCTURE WITH MULTIPLE THRESHOLD VOLTAGES AND METHOD MAKING THE SAME

(71) Applicant: Taiwan Semiconductor Manufacturing Company, Ltd., Hsin-Chu (TW)

(72) Inventors: Cheng-Ming LIN, Kaohsiung City (TW); Tsung-Kai CHIU, Hsinchu County (TW); Szu-Hua CHEN, Tainan City (TW); Wei-Yen WOON, Taoyuan City (TW); Szuya LIAO, Hsinchu (TW)

(21) Appl. No.: 19/216,212

(22) Filed: May 22, 2025

Related U.S. Application Data
(60) Provisional application No. 63/721,750, filed on Nov. 18, 2024.

(51) Int. Cl. H10D 84/01; H10D 84/85

(52) U.S. Cl. CPC H10D 84/0181; H10D 84/0177; H10D 84/851; H10D 84/856

(57) ABSTRACT

The present disclosure provides a method that includes forming active regions on a substrate; forming a gate dielectric layer on first channels in a bottom region and on second channels in a top region; forming dummy plugs on the gate dielectric layer in the bottom region; depositing a dipole material layer on the gate dielectric layer in the top region and on sidewalls of the dummy plugs; performing a first patterning process to the dipole material layer and the dummy plugs such that the dipole material layer and the dummy plugs are absent on the third active region; performing a first dipole driving process to the gate dielectric layer; performing a second patterning process to the dipole material layer such that the dipole material layer and the dummy plugs are absent on the second active region; and performing a second dipole driving process to the gate dielectric layer.

### PRIORITY

This application claims the benefits of and priority to U.S. Provisional Application No. 63/721,750, filed Nov. 18, 2024, which is herein incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC processing and manufacturing, and for these advancements to be realized, similar developments in IC processing and manufacturing are needed. For advanced technology such as CFETS, multi threshold voltage (Vt) devices are necessary to provide high speed or low standby power devices. Existing structure and methods include varying metal gate thicknesses or metal gate materials to create multi Vt offerings. However, relying on metal gate thickness and different metal materials in advanced technologies such as CFETs becomes difficult due to critical dimension scaling. Therefore, while existing threshold voltage tuning for IC devices are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 illustrates a cross-sectional view of a CFET structure having multiple Vt offerings, according to various aspects of the present disclosure.

FIG. 2A is a perspective view of the CFET structure, in portion or in entirety, according to various aspects of the present disclosure.

FIG. 2B is a cross-sectional view of the CFET structure, in portion or in entirety, according to various aspects of the present disclosure.

FIGS. 3A-3B is a flowchart of a method to form a monolithic CFET semiconductor device having multiple Vt offerings, in portion or in entirety, according to various aspects of the present disclosure.

FIGS. 4-12 illustrate cross-sectional views of the CFET structure having multiple Vt offerings at intermediate stages of fabrication processes in accordance with the method of FIGS. 2A-2B according to an embodiment of the present disclosure.

FIG. 13 is a flowchart of a method to form a CFET semiconductor structure having multiple Vt offerings, in portion or in entirety, according to various aspects of the present disclosure.

FIGS. 14A through 14G illustrates cross-sectional views of the CFET semiconductor structure at intermediate stages of fabrication processes according to some embodiments of the present disclosure.

FIGS. 15A and 15B illustrates cross-sectional views of the CFET semiconductor structure according to various embodiments of the present disclosure.

FIGS. 16A and 16B illustrates diagrams of the distributions of various dipole compositions and concentrations in the gate dielectric layers of bottom FETs and top FETs according to some embodiments of the present disclosure.

FIGS. 17A, 17B and 17C illustrates cross-sectional views of a CFET semiconductor structure, in portion, constructed according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to an integrated circuit (IC) structure and a method of making the same. Especially, the IC structure includes a field-effect transistor (FET) structure having multiple channels vertically stacked, such as multiple vertically stacked nanowires or nanosheets as channels. More specifically, the IC structure includes a complementary field-effect transistor (CFET) structure and the method of making the CFET. A CFET may include N-type FETs (NFETs) vertically over P-type FETs (PFETs) or P-type FETs vertically over the N-type FET. Each of the NFETs and PFETs further includes multiple channels vertically stacked over.

The semiconductor integrated circuit industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down has also increased the complexity of IC structures (such as three-dimensional transistors) and processing and, for these advancements to be realized, similar developments in IC processing and manufacturing are needed. For example, device performance (such as device performance degradation associated with various defects) and fabrication cost of field-effect transistors become more challenging when device sizes continue to decrease, especially for CFET structure.

When CFET devices are formed, such as by a monolithic process, an etching process is applied to etch metal for dual metal gates may attack the gate dielectric layer, such as a high-k (HK) dielectric material layer, and induce device degradation. Furthermore, when high thermal process and heavy dipole atom concentration is needed for ultralow threshold voltage applications, which may lead to degradation of contact resistance and channel mobility. Furthermore, various patterning processes including vertical patterning and horizontal patterning introduce additional issues. For example, the horizontal patterning requires hard mask and additional etching, leading to increased cost, residuals and profile degradation; and the vertical patterning causes material loss (such as dipole material loss) of the top FETs. The disclosed CFET structure and the method making the same eliminate implements a dipole treatment process to address those issues.

The present disclosure is generally related to an IC structure and the fabrication thereof, and more particularly to methods of fabricating field-effect transistors (FETs), such as fin-like FETs (FinFETs), gate-all-around FETs (GAA FETs), complimentary FETs (CFETs) and/or other FETs. Particularly, the disclosed semiconductor structure includes CFETs, which further include bottom FETs and top FETs stacked on the bottom FETs. The disclosed semiconductor structure includes CFETs formed by a monolithic process and a dipole treatment process tuned to achieve multiple threshold voltages in FETs and address the above issues. However, it is understood that the semiconductor structure formed by the disclosed method is not limited to the CFETs formed by a monolithic method, it can be applied to CFETs formed by other method, such as formed by a sequential method.

The IC structure includes CFET devices having multiple threshold voltage (Vt) offerings for optimized performance in targeted applications (e.g., high speed or low standby power devices). However, due to the complexity of a CFET structure and to address the CFET critical dimension limitations, integrating dipoles become more important for “volume-less” Vt tuning. That is, instead of increasing the volume dimension of a metal gate structure for Vt tuning, dipoles are driven into the gate structures without increasing the volume of the metal gate structure. For enhanced performance and device flexibility, a tunable dipole treatment is combined with multi patterning on CFETs for variable Vt Tuning. The combination of multi-patterning (dipole patterning) and multi-annealing (dipole loops) on CFETs with dipoles offer volume-less multi-Vt devices that satisfy critical dimension limitations and provide large range of threshold voltages. For example, different CFET gate structures of the same size may be doped differently to have different threshold voltages. For another example, NFET and PFET gate regions of a same CFET may be doped differently to have different threshold voltages. Yet in another example, gate regions within the NFET or PFET of a same CFET may be doped differently from channel to channel, offering different threshold activation voltages for a single NFET or PFET.

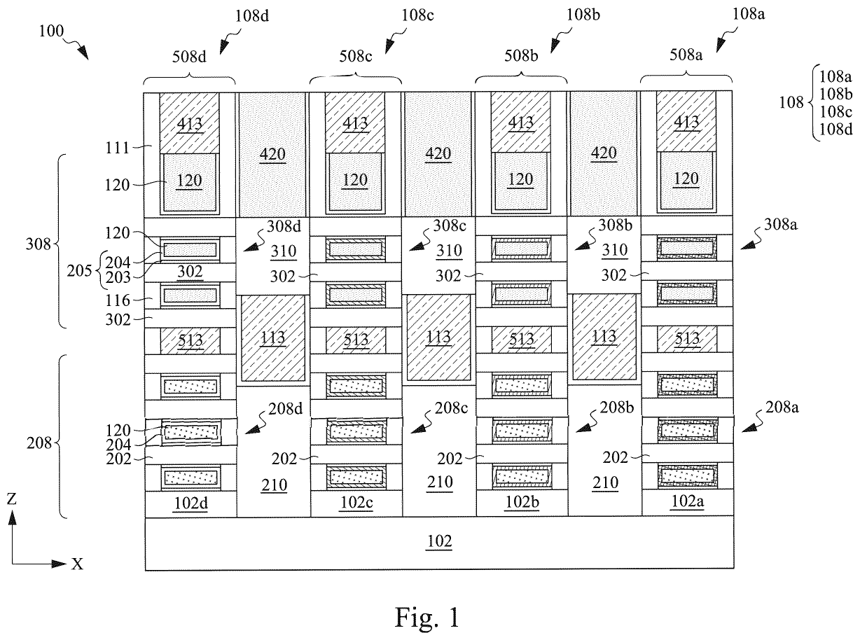

FIG. 1 illustrates a cross-sectional view of an IC structure having CFET devices (or simply IC structure) 100 with multiple Vt offerings. As will be explained in more detail below, the multiple Vt offering is effectuated through iteratively doping respective gate dielectric layers 205 in different CFET gate regions 108. As an exemplary embodiment, FIG. 1 shows four CFET gate regions 108a, 108b, 108c, and 108d over channel regions 102a, 102b, 102c, and 102d protruding from a substrate 102. The channel regions 102a, 102b, 102c, and 102d include semiconductor channels 202, 302. CFET gate regions 108a, 108b, 108c, and 108d include (CFET) metal gate structures 508a, 508b, 508c, and 508d. Stacks of semiconductor channels 202 and/or 302 are disposed over respective channel regions 102a, 102b, 102c, and 102d. In each of the CFET gate regions 108, the semiconductor channels 202/302 are wrapped around and interposed by respective CFET metal gate structures 508a, 508b, 508c, and 508d, each having a gate dielectric layer 205 and a metal gate electrode 120 on the gate dielectric layer 205. A top portion of the metal gate electrode 120 is disposed over the topmost channels 302 of each stack. In the disclosed embodiment, the gate dielectric layer 205 further includes an interfacial layer 203 disposed on the respective semiconductor channel 202, 302; and a high-k (HK) dielectric layer 204 disposed on the interfacial layer 203. In the disclosed embodiment, the NFETs are stacked on the PFETs. However, it is not intended to be limiting. In alternative embodiment, the PFETs are stacked on the NFETs.

Still referring to FIG. 1, the CFET gate regions 108 include NFET gate regions 308 over PFET gate regions 208. More specifically, a NFET gate region 308 includes a metal gate structure for a NFET; and a PFET gate region 208 includes a metal gate structure for a PFET. For example, an NFET gate region 308a is over a PFET gate region 208a; an NFET gate region 308b is over a PFET gate region 208b; an NFET gate region 308c is over a PFET gate region 208c; and an NFET gate region 308d is over a PFET gate region 208d. In some embodiments, the NFET gate regions 308 include gate dielectric layers 205 doped in various concentrations by a suitable dipole dopant, such as n-type dipoles, for reducing the threshold voltage of the NFET. In some embodiments, the PFET gate regions 208 include gate dielectric layers 205 doped in various concentrations by a suitable dipole dopant for reducing the threshold voltage of the PFET. The gate dielectric layers 205 in the NFET gate regions 308 surround semiconductor channels 302 to form NFETs, and the gate dielectric layers 204 in the PFET gate regions 208 surround semiconductor channels 202 to form PFETs. Each of the respective gate dielectric layers 205 are surrounded by the metal gate electrode 120. Especially, a dipole material layer (such as n-type dipole materials) is used with multiple patterning processes and multiple drive-in processes to introduce the dipole dopants into the gate dielectric layer 205 with different concentrations for different FETs to achieve tuning threshold voltages of NFETs and PFETs for different CFET devices.

Still referring to FIG. 1, the different dopant concentrations and compositions in the gate dielectric layers 204 for NFET gate regions 308a, 308b, 308c, and 308d are illustratively shown by different density of a first pattern fill. For example, in the NFET gate region 308a, n-type dipoles are driven into the gate dielectric layers 205 with a first doping concentration; in the NFET gate region 308b, the n-type dipoles are driven into the gate dielectric layers 205 with a second doping concentration; in the NFET gate region 308c, the n-type dipoles are driven into the gate dielectric layers 205 with a third doping concentration; and in the NFET gate region 308d, either no dipole treatment or with other different doping compositions and concentrations. Dipole treatments include multiple dipole patterning processes and multiple drive-in processes.

Still referring to FIG. 1, the IC structure 100 includes CFET devices having NFETs and PFETs stacked and with various threshold voltages. The IC structure 100 includes CFET metal gate structures 508a, 508b, 508c, and 508d in the CFET gate regions 108a, 108b, 108c, and 108d, in which both PFETs and NFETs formed on a same semiconductor substrate. In each respective metal gate structure 508a-508d, a metal gate electrode 120 is filled in between semiconductor channels 202/302 in both the PFET and NFET gate regions 208 and 308. Due to the dipole treatment processes, the gate dielectric layer is characteristically changed but the dimensions remain. Accordingly, the dimensions of the metal gate electrode 120 across CFET metal gate structures 508a-508d remain the same. That is, gate dimensions are not changed to vary Vt across different CFET devices. For example, a thickness of a portion of the metal gate electrode 120 wrapping around a semiconductor channel 202/302 for a high Vt CFET is substantially the same as a thickness of a portion of the metal gate electrode 120 wrapping around a semiconductor channel 202/302 for a low Vt CFET. As shown in FIG. 1, the thickness of the wrapping portions of metal gate electrode 120 across the CFET metal gate structures 508a-508d are the same. In the illustrated embodiment, the IC structure 100 having CFETs is formed by a method referred to as a monolithic process. However, it is not intended to be limiting. The same dipole treatment method can also be used to an IC structure having CFETs formed by other method, such as sequential method.

Although FIG. 1 shows an increasing gradient of dipole dopant concentration in the gate dielectric layers 204 from left to right (i.e., from the CFET metal gate structures 508d to the CFET metal gate structures 508a), the present disclosure is not limited thereto. Note that gate dielectric layer may include an interfacial layer 203 and a high-k dielectric layer 204, collectively referred to as gate dielectric layer 205, the details of the gate dielectric layer will be further described later. Depending on the dipole patterning process, different combinations of dipole dopant compositions and concentrations are possible from one CFET gate structure to another. Further, although FIG. 1 is described such that within a same CFET metal gate structure (e.g., 508a), the respective PFET and NFET gate regions (e.g., 208a and 308a) have a dipole process performed, the present disclosure is not limited thereto. Depending on the dipole process, different combinations of dipole dopant compositions and concentrations between PFET and CFET gate regions of a same CFET is also possible. Even further, although FIG. 1 shows NFET gate regions 308 over PFET gate regions 208 for a CFET device where the top device is an NFET and the bottom device is a PFET, the present disclosure is not limited thereto. Aspects of the present disclosure may equally apply to CFET devices where the top devices are PFETs and the bottom devices are NFETs where PFET gate regions 208 are over the NFET gate regions 308. Additional features not described with respect to FIG. 1 will be made apparent by following figures when describing the formation of an IC structure 100.

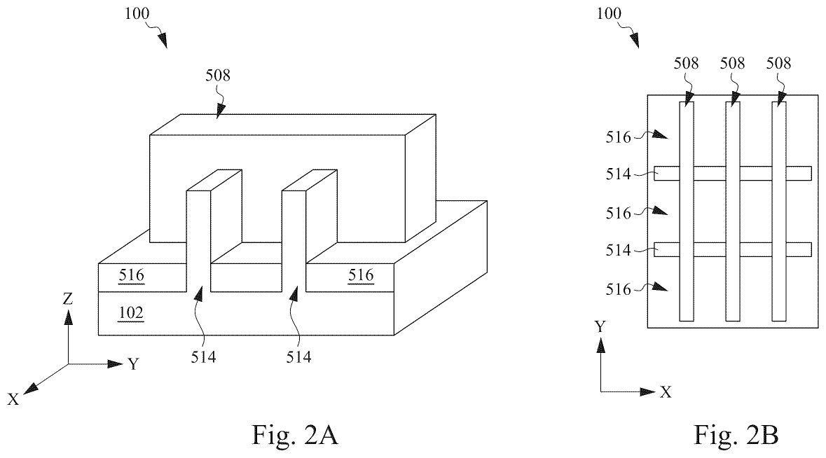

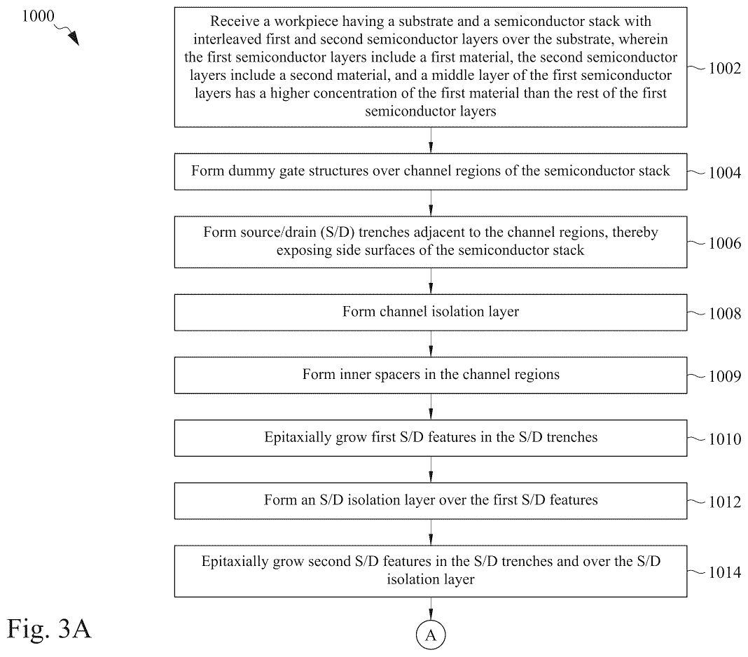

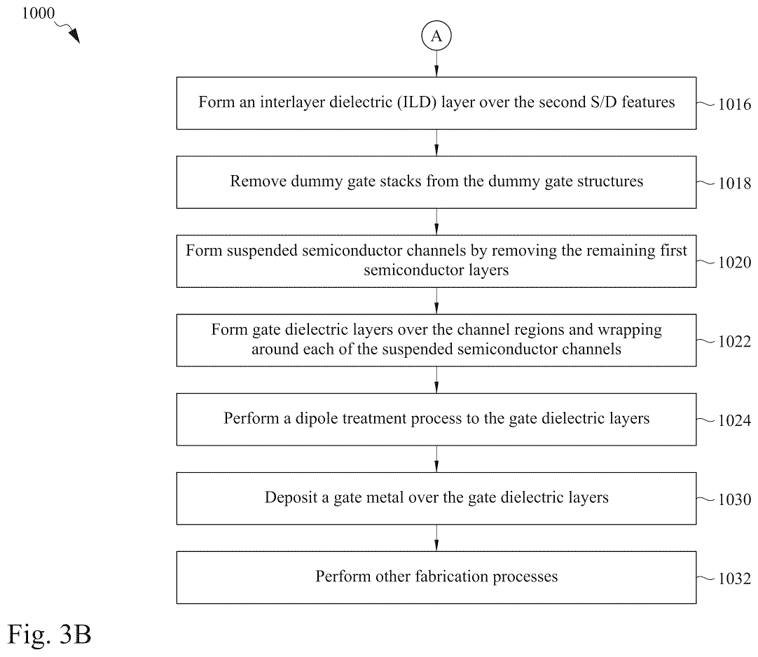

FIG. 2A is a perspective view; and FIG. 2B is a top view of the IC structure 100, in portion, constructed according to some embodiments. FIGS. 3A-3B is a flowchart of a method 1000 to form the IC structure 100 having multiple Vt offerings, in portion or in entirety, according to various aspects of the present disclosure. The method 1000 is briefly described below with reference to FIGS. 1, 2A-2B, 3A-3B, and other figures.

At operation 1002, the method 1000 receives or is provided with an IC structure (or a workpiece) 100 having a substrate 102 and a semiconductor stack with interleaved first and second semiconductor layers over the substrate. The first semiconductor layers include a first material, the second semiconductor layers include a second material, and a middle layer of the first semiconductor layers has a higher concentration of the first material than the rest of the first semiconductor layers. The first and second semiconductor layers are patterned to form one or more semiconductor stack as active regions, such as fin active regions.

The substrate 102 may include an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor, such as SiGe, GaAsP, AlInAs, AlGaAs, GaInAs, GaInP, GaInAsP, and/or other suitable materials. The substrate 102 may be a single-layer material having a uniform composition. Alternatively, the substrate 102 may include multiple material layers having similar or different compositions suitable for IC device manufacturing. In one example, the substrate 102 may be a silicon-on-insulator (SOI) substrate having a silicon layer formed on a silicon oxide layer. In another example, the substrate 102 may include a conductive layer, a semiconductor layer, a dielectric layer, other layers, or combinations thereof.

In some embodiments where the substrate 102 includes various doped regions, such as doped wells and source/drain regions, disposed in or on the substrate 102. The doped regions may be doped with p-type dopants, such as phosphorus or arsenic, and/or n-type dopants, such as boron or BF₂, depending on design requirements. The doped regions may be directly formed on the substrate 102 (such as a p-well structure, an n-well structure, or a dual-well structure) or using a raised structure (such as an epitaxial S/D feature). Doped regions may be formed by implantation of dopant atoms, in-situ doped epitaxial growth, diffusion, and/or other suitable techniques.

The operation 1002 further includes patterning the semiconductor stack to form active regions 514 and forming isolation structures 516 to surround each active region and isolate the active regions 514 from each other. Each active region 514 may be suitable for providing an n-type FET (NFET), a p-type FET (PFET) or both. In some embodiments, the active regions 514 as illustrated herein may be suitable for providing CFETs, i.e., PFETs on bottom portion and NFETs on top portion. This configuration is for illustrative purposes only and is not intended to be limiting. The active regions 514 may be fabricated using suitable processes including photolithography and etch processes. The photolithography process may include forming a photoresist layer (or resist) overlying the substrate 102, exposing the resist to a pattern, performing post-exposure bake processes, and developing the resist to form a masking element (not shown) including the resist. The masking element is then used for etching recesses into the substrate 102, leaving the active regions 514 on the substrate 102. The etching process may include dry etching, wet etching, reactive ion etching (RIE), and/or other suitable processes.

Numerous other embodiments of methods for forming the active regions 514 may be suitable. For example, the active regions 514 may be patterned using double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the active regions 514.

The isolation structures 516 are surrounding various active regions 514 and separate the active regions 514 one from another. The isolation structures 516 may include silicon oxide, silicon nitride, silicon oxynitride, fluoride-doped silicate glass (FSG), a low-k dielectric material, and/or other suitable materials. The isolation structures 516 may include shallow trench isolation (STI) features. In one embodiment, the isolation structures 516 are formed by etching trenches in the substrate 102 during the formation of the active regions 514. The trenches may then be filled with one or more dielectric material described above by a deposition process, followed by a chemical mechanical planarization (CMP) process. The isolation structures 516 may be subsequently recessed, such as selective etching, such that a top surface of the isolation structures 516 is below a top surface of the active regions 514, defining the active regions 514 protruding above the isolation structure 516 with a height H_{f} for optimized coupling between the gate electrode and the channel. In some embodiments, the height H_{f} of the active regions 514 ranges between 40 nm and 80 nm. Other isolation structure such as field oxide, local oxidation of silicon (LOCOS), and/or other suitable structures may also be implemented as the isolation structures 516. Alternatively, the isolation structures 516 may include a multi-layer structure, for example, having one or more thermal oxide liner layers. The isolation structures 516 may be deposited by any suitable method, such as chemical vapor deposition (CVD), flowable CVD (FCVD), spin-on-glass (SOG), high-density plasma CVD (HDPCVD), high aspect ratio process (HARP), other suitable methods, or combinations thereof.

At operation 1004, the method 1000 forms dummy gate structures over channel regions of the semiconductor stack. The dummy gate structures include gate spacers and dummy gate stacks. In some embodiments, each dummy gate stack serves as a placeholder for subsequently forming a high-k metal gate structure (HKMG; where “high-k” refers to a dielectric material with a dielectric constant greater than that of thermal silicon dioxide, which is about 3.9). The dummy gate stack may include a dummy gate electrode and various other material layers. In some embodiments, the dummy gate electrode includes polysilicon. In the depicted embodiment, the dummy gate stack may include a dielectric layer disposed between the active regions 514 and the dummy gate electrode as an interfacial layer to the dummy gate stack. In some embodiments, the dummy gate stack is formed by deposition and a patterning process. The patterning process further includes photolithography process and etching. In the present embodiment, a hard mask is further used in the patterning process to form the dummy gate stack. As will be discussed in detail below, the dummy gate stack is replaced with the HKMG during a gate replacement process after other components (e.g., the S/D features) of the IC structure 100 are fabricated. Various material layers of the dummy gate stack may be formed by any suitable process, such as CVD, PVD, ALD, other suitable processes, or combinations thereof. In some embodiments, the dummy gate stacks are formed by a suitable procedure, such as a procedure that includes depositing various gate material including hard mask; and patterning the gate materials by a photolithography process and etching. The operation 1004 also includes forming a gate spacer layer (or simply a spacer layer or gate spacers) on the sidewalls of the dummy gate stack. The spacer layer is formed by deposition and anisotropic etching. The spacer layer may include multiple films of different composition. In some embodiments, the spacer layer includes a first spacer layer of silicon oxide, and a second spacer layer of silicon nitride disposed on the first spacer layer.

At operation 1006, the method 1000 forms source/drain (S/D) trenches adjacent to the channel regions 102a/102b/102c/102d, thereby exposing side surfaces of the semiconductor stack within a source/drain (S/D) region. In some embodiments, the operation 1006 forms the S/D trenches by a suitable etching process, such as a dry etching process, a wet etching process, an RIE process, or a combination thereof. In some embodiments, the method 1000 selectively removes the portions of the active regions 514 within the S/D regions without etching or substantially etching portions of the spacer layers formed on sidewalls of the dummy gate stacks. The etching process at operation 1006 may implement a dry etching process using an etchant including a bromine-containing gas (e.g., HBr and/or CHBR₃), a fluorine-containing gas (e.g., CF₄, SF₆, CH₂F₂, CHF₃, and/or C₂F₆), other suitable gases, or combinations thereof. The extent of which the active regions is removed may be controlled by adjusting the duration of the etching process.

At operation 1008, the method 1000 form a channel isolation layer 513. The channel isolation layer 513 is formed between the top channels and bottom channels to provide isolation therebetween. The channel isolation layer 513 is formed by any suitable method. In some embodiments, the formation of the channel isolation layer 513 includes performing a selective etching process to remove the middle layer in the semiconductor stack, resulting in gaps between the bottom channels and top channels; refilling one or more dielectric material by deposition (such as CVD, other suitable deposition method or a combination thereof), and then performing a dry etching process to remove the excessive portion deposited in the S/D trenches. In an alternative embodiment, the channel isolation layer 513 may be formed at a later stage, such as be formed after the dummy gates are removed and before the metal gates (or HKMG) are formed. In this case, the middle layer is selectively removed; a dielectric layer is formed therein by deposition; and a dry etch may be further applied to remove the excessive portions of the deposited dielectric material.

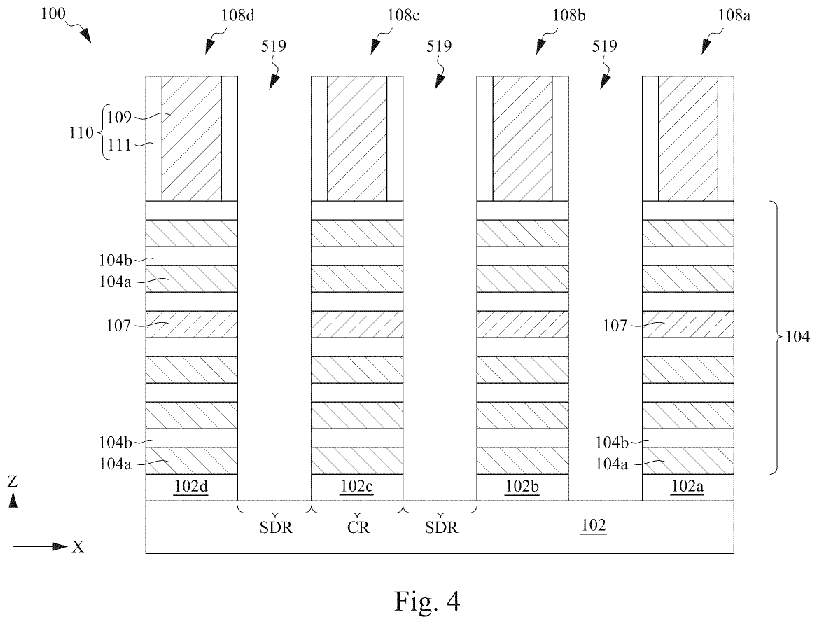

With respect to selectively etching the middle layer 107 (such as illustrated in FIG. 4), various etching parameters can be tuned such as etchant composition, etching temperature, etching solution concentration, etching time, etching pressure, source power, RF bias voltage, RF bias power, etchant flow rate, other suitable etching parameters, or combinations thereof. For example, an etchant is selected to etch the material of the middle layer 107 (e.g., highest concentration of germanium) at a higher rate than the semiconductor layers 104a (e.g., middle concentration of germanium). The etching process is a dry etching process, a wet etching process, other suitable etching process, or combinations thereof. In some embodiments, a dry etching process (such as an RIE process) utilizes a fluorine-containing gas (for example, SF6) to selectively etch the semiconductor layers. In some embodiments, a ratio of the fluorine-containing gas to an oxygen-containing gas (for example, O2), an etching temperature, and/or an RF power may be tuned to selectively etch silicon germanium (or silicon). In some embodiments, a wet etching process is performed with an etching solution that includes ammonium hydroxide (NH4OH) and water (H2O) to selectively etch the germanium-containing semiconductor layers. In some embodiments, a chemical vapor phase etching process using hydrochloric acid (HCl) is used.

At operation 1009, the method 1000 form inner spacers 116 underlying the gate spacer 111 on the sidewall of the dummy gate stack 109 (as illustrated in FIG. 4). The inner spacers 116 are formed vertically between the adjacent first semiconductor layers. The operation 1009 may include laterally etching; deposition; and anisotropic etching.

At operation 1010, the method 1000 epitaxially grows first S/D features (or bottom S/D features) 210 in the S/D trenches. The first S/D feature 210 may include multiple epitaxial semiconductor layers, such as a first semiconductor layer and a second semiconductor layer on the first semiconductor layer. In some embodiments, the first and second semiconductor layers differ in amount of dopant included therein. In some examples, the amount of dopant included in the first semiconductor layer is less than that included in the second semiconductor layer, to minimize potential leak currents and reduce the contact resistance. The dopant is in-situ introduced into the S/D feature 210 during the selective epitaxial growth. In some embodiments, the first and second semiconductor layers differ in composition to provide other advantages, such as strain effect to enhance the carrier mobility and the transistor speed. For example, the first and second semiconductor layers include silicon and silicon germanium, respectively, or vice versa, depending on the transistor types.

The first S/D feature 210 may be formed by any suitable method, such as MBE, MOCVD, other suitable epitaxial growth processes, or combinations thereof. The S/D feature 210 may be suitable for a p-type FinFET device (e.g., a p-type epitaxial material) or alternatively, an n-type FinFET device (e.g., an n-type epitaxial material). The p-type epitaxial material may include one or more epitaxial layers of silicon germanium (epi SiGe), where the silicon germanium is doped with a p-type dopant such as boron, gallium, indium, and/or other p-type dopants. The formation of the first S/D features 210 may further include etching to recess the semiconductor layers so to be below the channel isolation layer.

At operation 1012, the method 1000 forms an S/D isolation layer 113 on the bottom S/D features 210. The S/D isolation layer 113 includes one or more dielectric material to provide isolation between the bottom S/D features 210 and the top S/D features 310 to be formed. The S/D isolation layer 113 can be formed by any suitable method, such as a method that includes bottom-up deposition. In another example, the method includes deposition. CMP, and etching to recess. In yet another example, the method includes deposition to form a thin dielectric layer; performing a tiled ion treatment to treat the sidewall portions of the deposited dielectric layer; and performing a selective etching process to remove the treated portion of the dielectric layer.

At operation 1014, the method 1000 epitaxially grows second S/D features (or top S/D features) 310 in the S/D trenches and over the S/D isolation layer 113. The S/D feature 310 may be formed by any suitable method, such as MBE, MOCVD, other suitable epitaxial growth processes, or combinations thereof. The S/D feature 310 may be suitable for an n-type FinFET device (e.g., an n-type epitaxial material) or alternatively p-type FinFET device (e.g., a p-type epitaxial material). The n-type epitaxial material may include one or more epitaxial layers of silicon (epi Si) or silicon carbon (epi SiC), where the silicon or silicon carbon is doped with an n-type dopant such as arsenic, phosphorus, and/or other n-type dopants.

At operation 1016, the method 1000 forms an interlayer dielectric (ILD) layer 413 on the workpiece 100, such as on the gate structures 508 to provide isolation functions among various conductive features. The ILD layer 413 may be formed by deposition and CMP. The ILD layer includes one or more dielectric material, such as silicon oxide, tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), low-k dielectric material or other suitable dielectric material. In various embodiments, the ILD layer 413 is deposited by CVD, HDPCVD, sub-atmospheric CVD (SACVD), HARP, a flowable CVD (FCVD), and/or a spin-on process. In some embodiments, forming the ILD layer 413 further includes performing a CMP process to planarize a top surface, such that the top surfaces of the dummy gate stacks are exposed. In some embodiments, a bottom contact etch-stop layer (BCESL) is deposited between the ILD layer and the substrate 102 with a composition different from that of the ILD layer, such as silicon nitride, to achieve etch selectivity.

At operation 1018, the method 1000 removes dummy gate stacks from the dummy gate structures by etch, resulting in gate trenches in the ILD layer 413. The operation 1018 may additionally include patterning with photolithography process. Forming the gate trenches may include one or more etching processes that are selective to the materials included in the dummy gate stacks (e.g., polysilicon included in the dummy gate electrodes). The etching processes may include dry etching, wet etching, RIE, or other suitable etching methods, or combinations thereof.

At operation 1022, the method 1000 forms suspended semiconductor channels 202, 302 by removing the remaining first semiconductor layers using a selective etching process. This operation is also referred to as a channel release process.

At operation 1024, the method 1000 forms a gate dielectric layers 205 over the channel regions and wrapping around each of the suspended semiconductor channels 202, 302. In some embodiments, the gate dielectric layers 205 include an interfacial layer 203, such as a silicon oxide layer and a high-k dielectric layer 204. The high-k dielectric material layer 204 may include one or more high-k dielectric materials (or one or more layers of high-k dielectric materials), such as hafnium silicon oxide (HfSiO), hafnium oxide (HfO₂), alumina (Al₂O₃), zirconium oxide (ZrO₂), lanthanum oxide (La₂O₃), titanium oxide (TiO₂), yttrium oxide (Y₂O₃), strontium titanate (SrTiO₃), or a combination thereof.

At operation 1026, the method 1000 performs a dipole treatment process to the gate dielectric layers 205. As described above, the dipole treatment process is designed according to various embodiments of the present disclosure to eliminate various issues, including material loss, and vertical and horizontal patterning challenges, and to tune CFETs with various threshold voltages. That is, instead of increasing the volume dimension of a metal gate structure for Vt tuning, dipoles are driven into the gate structures without increasing the volume of the metal gate structure. For enhanced performance and device flexibility, a tunable N-type dipole (such as lanthanum oxide) and/or a tunable P-type dipole (such as zinc oxide) are combined with multiple patterning and multiple drive-in processes for variable Vt Tuning. The combination of multi-patterning and multiple drive-in (multi-annealing) on CFET with n-type and/or p-type specific dipoles offer volume-less multi-Vt devices that satisfy critical dimension limitations and provide large range of threshold voltages. For example, different CFET gate structures of the same size may be doped differently to have different threshold voltages. For another example, NFET and PFET gate regions of a same CFET may be doped differently to have different threshold voltages. Yet in another example, gate regions within a same NFET or PFET of a CFET may be doped differently from channel to channel, offering different threshold activation voltages for a single NFET or PFET. The dipole treatment process will be further described in detail with reference to other figures.

At operation 1030, the method 1000 forms gate electrodes 120. The gate electrodes 120 for PFETs and NFETs may include different types of work function metals and may additionally include other metals, such fill metal, metal cap and/or glue metal. In some embodiments, the dipole treatment process adopts only n-type dipole material. The gate electrodes 120 in the bottom gate region 208 include p-type work function metal, such as titanium nitride, tantalum nitride, tungsten nitride, other suitable p-type work function metal or a combination thereof; and the gate electrodes 120 in the top gate region 308 include n-type work function metal, such as: tantalum (Ta); tantalum aluminum (TiAl), TiAlC, TiAlO and TiAlN, other suitable n-type work function metal or a combination thereof. In some embodiments, the P-type work function metal may additionally or alternatively include ruthenium (Ru), molybdenum (Mo), tungsten (W), platinum (Pt), titanium (Ti), aluminum (Al), tantalum carbide (TaC), tantalum carbide nitride (TaCN), tantalum silicon nitride (TaSiN), titanium silicon nitride (TiSiN), other suitable materials, or combinations thereof.

The method 1000 may include other operations 1032 before, during and after various operations described above. For example, the method 1000 includes forming an interconnect structure with various conductive features to coupled CFETs and other devices formed on the substrate 102 into an integrated circuit. The interconnect structure includes metal lines distributed in multiple metal layers; contacts to vertically connect devices to metal lines; and vias to vertically connect metal lines in the adjacent metal layers. For examples, contacts 420 to S/D features 310 are shown in FIG. 1 for illustration. The method 1000 may further includes forming a passivation structure on the interconnect structure. The passivation structure provides sealing effect to protect the integrated circuit from the environment, such as moisture; provides a redistribution layer to redistribute the bonding structure; and provides the bonding structure to couples the interconnect structure to the packaging, such as printed circuit board.

The method 1000 may perform further steps to complete fabrication of the IC structure 100. Additional processing is contemplated by the present disclosure. Additional operations can be provided before, during, and after method 1000, and some of the operations described can be moved, replaced, or eliminated for additional embodiments of method 1000.

FIGS. 4-12 illustrate cross-sectional views of an IC structure 100 having CFETs with multiple Vt offerings at intermediate stages of fabrication and processed in accordance with the method 1000 of FIGS. 3A-3B. The IC structure 100 may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random-access memory (NVRAM), a flash memory, an electrically erasable programmable read only memory (EEPROM), an electrically programmable read-only memory (EPROM), other suitable memory type, or combinations thereof.

As shown in FIG. 4 and referring to operation 1002, the method 1000 receives or is provided with a workpiece having a substrate 102 and a semiconductor stack 104 with interleaved first and second semiconductor layers 104a and 104b over the substrate 102. The substrate 102 may be a silicon (Si) substrate, or a substrate having other semiconductor materials such as germanium (Ge), silicon carbide (SiC), silicon germanium (SiGe), or diamond. The semiconductor stack 104 may also be referred to as active regions that extend lengthwise along the x direction. Additional semiconductor stacks 104 may be formed in parallel along the y direction, and the semiconductor stacks 104 are separated from each other by an isolation structure such as a shallow trench isolation (STI) structure (not shown).

The first semiconductor layers 104a have a different material composition than the second semiconductor layers 104b to achieve etch selectivity. For example, each of the first semiconductor layers 104a is made of silicon germanium and each of the second semiconductor layers 104b is made of silicon. Note that the first semiconductor layers 104a of the semiconductor stack 104 includes a middle layer 107 that has a different concentration makeup than the rest of the first semiconductor layers 104a. For example, the middle layer 107 is made of silicon germanium but has a greater concentration of germanium than the first semiconductor layers 104a. In furtherance of the example, the first semiconductor layers 104a are SiGe layers with germanium concentration ranging between 20% and 25% (atomic percentage), and the middle layer 107 is a silicon germanium layer with germanium concentration greater than 30% (atomic percentage), such as ranging between 40% and 60%. This allows for selective etching of the middle layer 107 in a later process step, where the middle layer 107 is replaced with a channel isolation layer to separate top devices from bottom devices of the CFETs of the IC structure 100. Note that the middle layer 107 does not necessarily have to be in the exact middle to separate a top device from a bottom device. This layer may be closer to the top of the stack or closer to the bottom of the stack, and as such, it is possible that the bottom device will have more or less semiconductor channels than the top device. In an embodiment shown in FIG. 4, the first semiconductor layers 104a include a first material (i.e., germanium), the second semiconductor layers 104b include a second material (i.e., silicon), and a middle layer 107 includes the first material with a higher concentration of the first material (i.e., germanium) than the first semiconductor layers 104a. The second semiconductor layers 104b may be of a same material composition as the substrate 102. The operation 1002 also includes forming active regions and isolation structures as described above.

Still referring to FIG. 4, the method 1000 at operation 1004 forms dummy gate structures 110 over channel regions CR of the semiconductor stack 104. The channel regions CR include channel regions 102a-102d that are part of the substrate 102. Each of the dummy gate structures 110 includes a dummy gate stack 109 and gate spacers 111 over sidewalls of the dummy gate stack 109. The dummy gate stack 109 may be made of polysilicon and the gate spacers 111 may be made of silicon oxide, silicon nitride, silicon oxycarbide, silicon oxycarbonitride, silicon carbonitride, metal nitride, or a suitable dielectric material.

Still referring to FIG. 4, the method 1000 at operation 1006 forms source/drain (S/D) trenches 519 in S/D regions SDR adjacent to the channel regions CR, thereby exposing side surfaces of the semiconductor stack 104. The S/D trenches 519 may be formed by a dry etching process, a wet etching process, other suitable etching process, or combinations thereof. In some embodiments, the etching process is a multi-step etch process. For example, the etching process may include alternative etchants to separately and alternately remove first semiconductor layers 104a and semiconductor layers 104b. In some embodiments, parameters of the etching process are configured to selectively etch the semiconductor stack 104 with minimal (to no) etching of dummy gate structures 110 (i.e., dummy gate stacks 109 and gate spacers 111). In some embodiments, a lithography process is performed to form a patterned mask layer that covers dummy gate structures 110 and/or portions of an isolation structure between semiconductor stacks 104, and the etching process uses the patterned mask layer as an etch mask when forming the S/D trenches 519. Note that the etching process may also etch slightly into the substrate 102. That is, when forming the S/D trenches 519, the substrate 102 may be recessed to form protruding portions that define the channel regions 102a, 102b, 102c, and 102d.

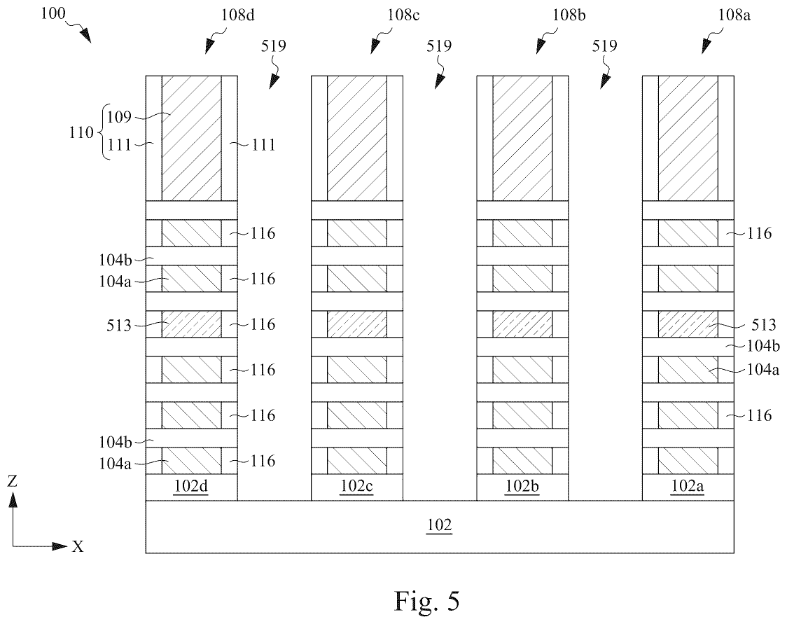

Now referring to FIG. 5, In some embodiments, the method 1000 includes an operation 1008 to form the channel isolation layer 513 before the formation of the inner spacers 116. The formation of the channel isolation layer 513 includes selective etching the middle layer 107, resulting in gaps between the bottom channels and top channels; depositing one or more dielectric material; and dry etching to remove excessive portions in the S/D trenches 519.

Still referring to FIG. 5, the method 1000 at operation 1009 forms inner spacers 116 in the channel regions CR along sidewalls of the first semiconductor layers 104a by any suitable process. For example, an etch process is first performed to selectively etch sidewalls of the first semiconductor layers 104a without etching (or substantially etching) the second semiconductor layers 104b, thereby forming lateral recesses. In other words, the side etch process is configured to laterally etch (e.g., along the x direction) first semiconductor layers 104a, thereby reducing a length of first semiconductor layers 104a along the x direction. The etch process is a dry etching process, a wet etching process, other suitable etching process, or combinations thereof. After the side etch process is performed, lateral recesses (or air gaps) are formed under each of the second semiconductor layers 104b. Then, as shown in FIG. 5, inner spacers 116 are formed in each of the air gaps. The inner spacers 116 are disposed directly below the gate spacers 111, and they may be substantially vertically aligned with the gate spacers 111 along the z direction.

The inner spacers 116 may be formed by a spacer deposition process and an anisotropic etching process. For example, a spacer deposition process is performed to form a spacer layer over the dummy gate structures 110 and over features defining the S/D trenches 519 (e.g., semiconductor layers 104a, semiconductor layers 104b, and substrate 102). The spacer deposition process may include processes such as CVD, PVD, ALD, HDPCVD, MOCVD, RPCVD, PECVD, LPCVD, ALCVD, APCVD, plating, other suitable methods, or combinations thereof. The spacer layer partially (and, in some embodiments, completely) fills the S/D trenches 519. The spacer deposition process is configured to ensure that the spacer layer fills the air gaps between semiconductor layers 104b and between semiconductor layers 104b and the respective channel regions 102a-102d under gate spacers 111. The anisotropic etching process is then performed that selectively etches the spacer layer to form inner spacers 116 as depicted in FIG. 4 with minimal (to no) etching of semiconductor layers 104b, dummy gate stacks 109, and gate spacers 111. In the disclosed embodiment, the anisotropic etching process includes a plasma etch, other suitable etch process or a combination thereof. The spacer layer (and thus inner spacers 116) includes a material that is different than a material of semiconductor layers 104b and a material of gate spacers 111 to achieve desired etching selectivity during the gate spacer etching process. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material.

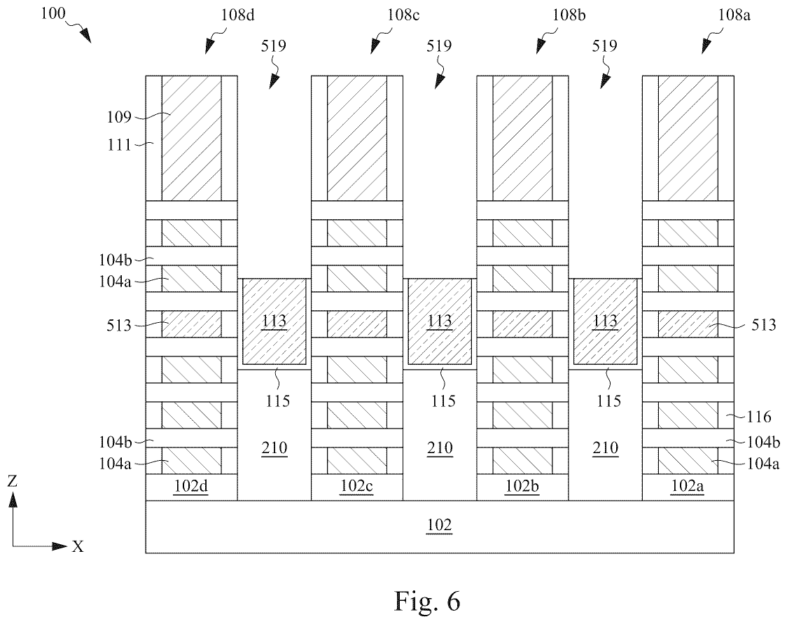

Now referring to FIG. 6, the method 1000 at operation 1010 epitaxially grows first S/D features 210 in the S/D trenches 519 for bottom FETs of the IC structure 100. The bottom FETs may be PFETs in the present embodiments (or NFETs in alternative embodiments). As such, the first source/drain features 210 may include p-type source/drain features that correspond with p-type transistor regions (or alternatively n-type source/drain features that correspond with n-type transistor regions). In the illustrated embodiment, the bottom channels are channel for PFETs, and the first source/drain features 210 are p-type source/drain features. The first source/drain features 210 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of substrate 102 and/or semiconductor stacks 104 (in particular, semiconductor layers 104b). Epitaxial source/drain features are doped with p-type dopants (or alternatively n-type dopants). In some embodiments, for the p-type CFET transistors, first epitaxial source/drain features 210 include silicon germanium or germanium and can be doped with boron, other p-type dopant, or combinations thereof (for example, forming Si:Ge:B or Si:B epitaxial source/drain features). In some embodiments, for the n-type CFET transistors, first epitaxial source/drain features 210 include silicon and can be doped with phosphorous, arsenic, other n-type dopant, or combinations thereof (for example, forming Si:C epitaxial source/drain features, Si:P epitaxial source/drain features, or silicon carbon doped with phosphorus—SiC:P epitaxial source/drain features). In the embodiment shown, the first S/D features 210 are p-type S/D features for PFET devices.

Still referring to FIG. 6, the first S/D features 210 only partially fill the S/D trenches 519. Specifically, they are grown (or grown and recessed) to a height below the channel isolation layer 513 in the z direction. That is, the first S/D features 210 are in direct contact with semiconductor layers 104b for bottom transistor devices under the channel isolation layer 513, but not the semiconductor layers 104b above the channel isolation layer 513. Note that in some embodiments, like as shown, the first S/D features 210 need not be in direct contact with all the semiconductor layers 104b under the channel isolation layer 513. In some embodiments, the first S/D features 210 are formed by a procedure that includes epitaxial growth; performing a chemical mechanical polishing (CMP) process; and etching to selective recess.

Still referring to FIG. 6, the method 1000 at operation 1012 forms an S/D isolation layer 113 over the first S/D features 210. This may be done by first conformably depositing a dielectric liner such as an etch stop layer 115 by CVD, ALD or other suitable processes, then depositing the S/D isolation layer 113 over the etch stop layer 115. An etch process may follow to recess top surfaces of the S/D isolation layer 113 and etch stop layer 115. In some embodiments, the operation 1012 includes depositing the etch stop layer 115 and the S/D isolation layer 113, performing a chemical mechanical polishing (CMP), and etching to recess the deposited materials. In some embodiments, the operation 1012 may apply a bottom-up deposition. The etch stop layer 115 may include silicon nitride and the S/D isolation layer 113 may include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the S/D isolation layer 113 includes a low-k dielectric material.

The S/D isolation layer 113 only partially fill the S/D trenches 519 since second S/D features 310 are to be formed over the S/D isolation layer 113. However, although only partially filled, the S/D isolation layer 113 should be thick enough to isolate the first S/D features 210 from the later formed second S/D features 310. As such, in some embodiments, like as shown, the S/D isolation layer 113 (or etch stop layer 115) may be in direct contact with sidewalls of the second semiconductor layers 104b, thereby isolating them from contacting the first or second S/D features 210, 310. The S/D isolation layer 113 has a portion horizontally aligned with the middle layer 107 along the x direction. The S/D isolation layer 113 is separated from the middle layer 107 by inner spacers 116. In an embodiment, the S/D isolation layer 113 has a thickness in the z direction greater than a thickness of the channel isolation layer 513 (or the middle layer 107).

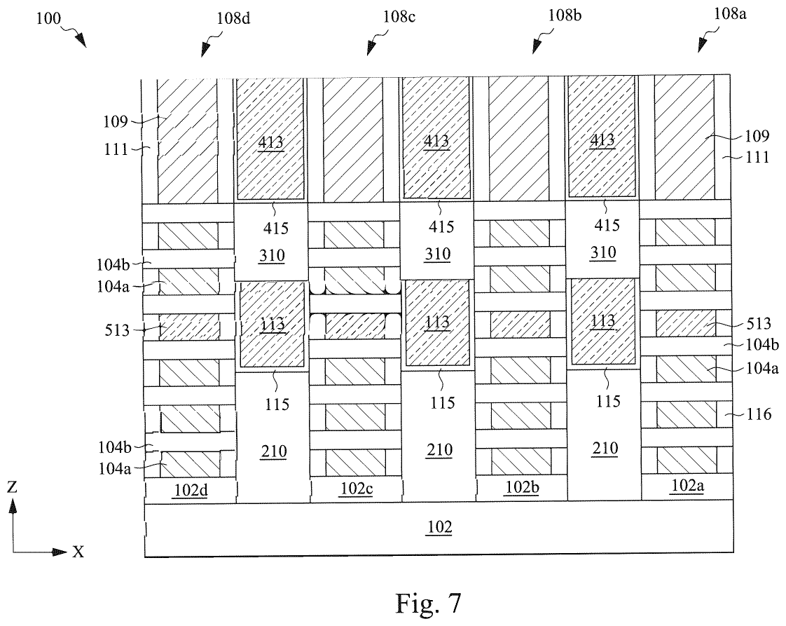

Now referring to FIG. 7, the method 1000 at operation 1014 epitaxially grows second S/D features 310 in the S/D trenches 519 and over the S/D isolation layer 113 for top FETs of the IC structure 100. The top FETs may be NFET transistor devices (or alternatively PFETs). As such, the second source/drain features 310 may include n-type source/drain features that correspond with n-type transistor regions or p-type source/drain features that correspond with p-type transistor regions. The second source/drain features 310 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of semiconductor stacks 104 (in particular, semiconductor layers 104b). Epitaxial source/drain features are doped with n-type dopants and/or p-type dopants. In some embodiments, for the NFETs, second epitaxial source/drain features 310 include silicon and can be doped with phosphorous, arsenic, other n-type dopant, or combinations thereof (for example, forming Si:C epitaxial source/drain features, Si:P epitaxial source/drain features, or silicon carbon doped with phosphorus-SiC:P epitaxial source/drain features). In some embodiments, for the PFETs, second epitaxial source/drain features 310 include silicon germanium or germanium and can be doped with boron, other p-type dopant, or combinations thereof (for example, forming Si:Ge:B epitaxial source/drain features). In the embodiment shown, the second S/D features 310 are n-type S/D features for NFET devices.

Still referring to FIG. 7, the second S/D features 310 may completely fill the S/D trenches 519 such that top surfaces of the second S/D features 310 are substantially coplanar with top surfaces of the topmost second semiconductor layers 104b. Alternatively, the second S/D features 310 may grow above the top surfaces of the topmost second semiconductor layers 104b. Note that the second S/D features 310 are in direct contact with semiconductor layers 104b for top transistor devices above the channel isolation layer 513, but not the semiconductor layers 104b below the channel isolation layer 513. Note that in some embodiments, like as shown, the second S/D features 310 need not be in direct contact with all the semiconductor layers 104b above the channel isolation layer 513.

Still referring to FIG. 7, the method 1000 at operation 1016 forms an interlayer dielectric (ILD) layer 413 over the second S/D features 310. This may be done by first conformably depositing a dielectric liner such as an etch stop layer 415 by CVD, ALD or other suitable processes, then depositing the ILD layer 413 over the etch stop layer 415. A planarization process such as CMP may follow to planarize top surfaces of the ILD layer 413, etch stop layer 415, and dummy gate structures 110. The etch stop layer 415 may include silicon nitride and the ILD layer 413 may include a dielectric material that includes for example, silicon oxide, silicon nitride, silicon oxynitride, tetraethoxysilane (TEOS) formed oxide, Phosphosilicate Glass (PSG), Boron-Doped Phosphosilicate Glass (BPSG), low-k dielectric material, other suitable dielectric material, or combinations thereof.

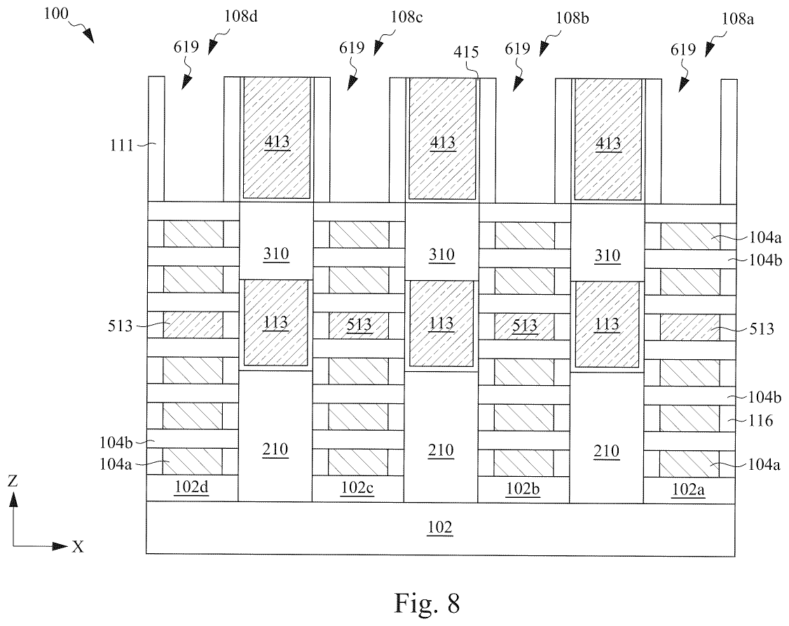

Now referring to FIG. 8, the method 1000 at operation 1018 removes dummy gate stacks 109 from the dummy gate structures 110. The dummy gate stacks 109 are removed by a suitable etching process, thereby resulting in gate trenches 619 and exposing the semiconductor stacks 104. The etching process is designed with an etchant to selectively remove the dummy gate stacks 109. In the depicted embodiment, an etching process completely removes dummy gate stacks 109 to expose surfaces of the semiconductor layers 104a and semiconductor layers 104b in the x-z plane. The etching process is a dry etching process, a wet etching process, other suitable etching process, or combinations thereof. In some embodiments, the etching process is a multi-step etch process. For example, the etching process may include alternative etchants to separately remove various layers of dummy gate stacks 109, such as the dummy gate electrode layers, the dummy gate dielectric layers, and/or the hard mask layers. In some embodiments, the etching process is configured to selectively etch dummy gate stacks 109 with minimal (to no) etching of other features of the IC structure 100, such as ILD layer 413, gate spacers 111, semiconductor layers 104a, and semiconductor layers 104b. In some embodiments, a lithography process is performed to form a patterned mask layer that covers the ILD layer 413 and/or gate spacers 111, and the etching process uses the patterned mask layer as an etch mask.

Still referring to FIG. 8, in an alternative embodiment, the middle layer 107 may be replaced with a channel isolation layer 513 at this stage if not being removed earlier. The middle layer 107 is removed by a suitable etching process. The etching process is designed with an etchant to selectively remove the middle layer 107. As described above, the middle layer 107 has a different concentration of materials such as heavier germanium concentration than other first semiconductor layers 104a (which also include germanium). This allows for selective etching of the middle layer 107 without etching the remaining semiconductor layers 104a. Thereafter, the air void that remains is filled with a dielectric material to form the channel isolation layer 513. The channel isolation layer 513 may include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the S/D isolation layer 113 includes a low-k dielectric material. In some embodiments, the formation of the channel isolation layer 513 includes etching, deposition, and anisotropic etch, such as plasma etch.

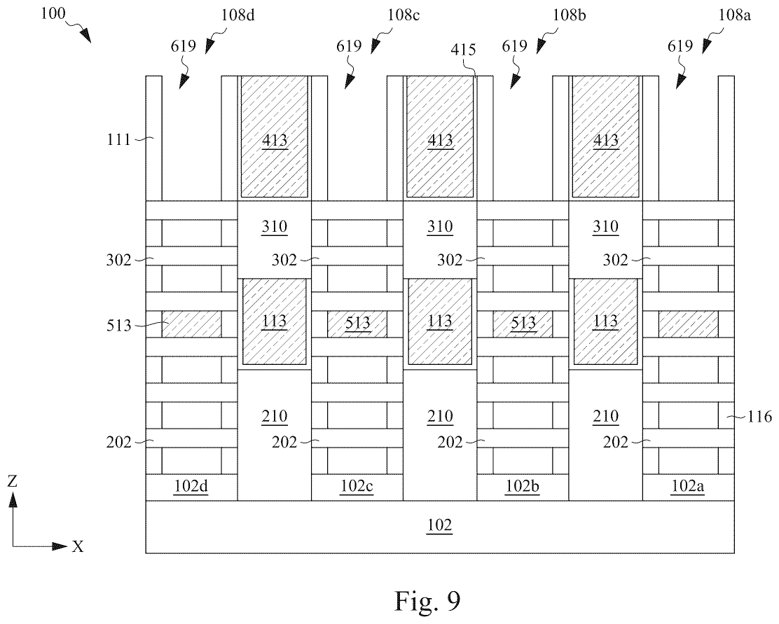

Now referring to FIG. 9, the method 1000 at operation 1022 forms suspended semiconductor channels 202/302 by removing the remaining first semiconductor layers 104a using a suitable etching process. The etching process is designed with an etchant to selectively remove the remaining first semiconductor layers 104a without substantially etching the second semiconductor layers 104b and the channel isolation layer 513. As such, the second semiconductor layers 104b become suspended semiconductor channels 202 and 302. The suspended semiconductor channels 202 refer to channel layers for the bottom FETs (e.g., PFET channels of the IC structure 100) and the suspended semiconductor channels 302 refer to channel layers for the top FETs (e.g., NFET channels of the IC structure 100). In the disclosed embodiment, the semiconductor channels 202 and the semiconductor channels 302 are different, such as different dopants, different in composition or a combination thereof. In furtherance of the embodiment, the semiconductor channels 202 are doped with n-type dopants, such as phosphorous; and the semiconductor channels 302 are doped with p-type dopants, such as boron. In some embodiments, the dopants are in-situ introduced into the channels when the semiconductor layers 104b are epitaxially grown. In some embodiments, the dopants may be introduced into the channels after the semiconductor layer 104b are epitaxially grown.

Various etching parameters can be tuned such as etchant composition, etching temperature, etching solution concentration, etching time, etching pressure, source power, RF bias voltage, RF bias power, etchant flow rate, other suitable etching parameters, or combinations thereof. The etching process is a dry etching process, a wet etching process, other suitable etching process, or combinations thereof. In some embodiments, a dry etching process (such as an RIE process) utilizes a fluorine-containing gas (for example, SF6) to selectively etch the semiconductor layers. In some embodiments, a ratio of the fluorine-containing gas to an oxygen-containing gas (for example, O2), an etching temperature, and/or an RF power may be tuned to selectively etch silicon germanium (or silicon). In some embodiments, a wet etching process is performed with an etching solution that includes ammonium hydroxide (NH4OH) and water (H2O) to selectively etch the germanium-containing semiconductor layers. In some embodiments, a chemical vapor phase etching process using hydrochloric acid (HCl) is used.

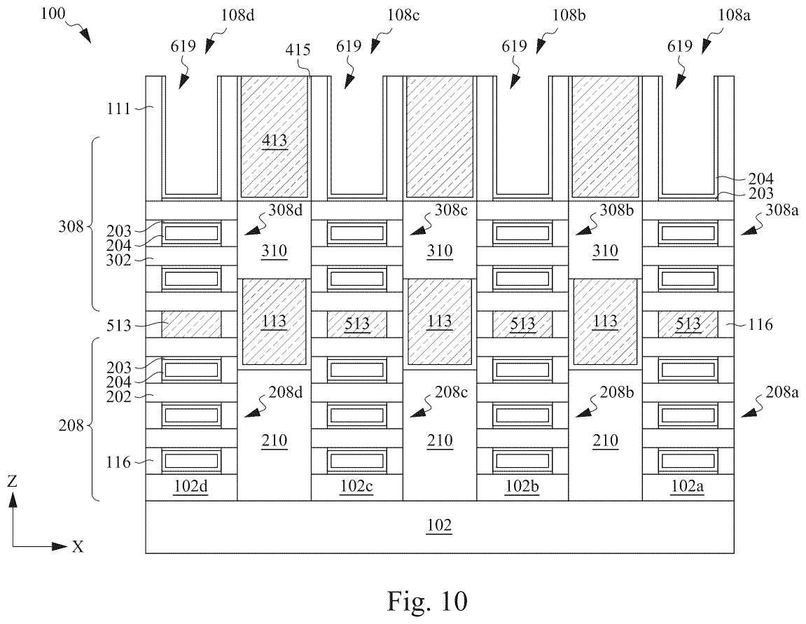

Now referring to FIG. 10, the method 1000 at operation 1024 forms gate dielectric layers 205 over the channel regions 102a-102d and wrapping around each of the suspended semiconductor channels 202/302. The gate dielectric layers 205 partially fills the gaps between the suspended semiconductor channels 202/302 and may include high-k dielectric materials such as HfO₂, HfSiO, HfSiO₄, HfSiON, HfLaO, HfTaO, HfTiO, HfZrO, HAlOₓ, ZrO, ZrO₂, ZrSiO₂, AlO, AlSiO, Al₂O₃, TIO, TiO₂, LaO, LaSiO, Ta₂O₃, Ta₂O₅, Y₂O₃, SrTiO₃, BaZrO, BaTiO₃(BTO), (Ba,Sr)TiO₃(BST), Si₃N₄, hafnium dioxide-alumina (HfO₂—Al₂O₃) alloy, other suitable high-k dielectric material, or combinations thereof. The gate dielectric layers 205 may be formed by any of the processes described herein, such as ALD, CVD, PVD, oxidation-based deposition process, other suitable process, or combinations thereof. In an embodiment, the gate dielectric layers 205 includes an interfacial layer 203 disposed on the channel layers 202/302 and a high-k dielectric layer 204 disposed on the interfacial layer 203. The interfacial layers 203 may be formed by thermal oxidation, chemical oxidation, ALD, CVD, or other suitable processes. The interfacial layers 203 may include a dielectric material, such as SiO₂, HfSiO, SiON, other silicon-containing dielectric material, other suitable dielectric material, or combinations thereof. In some embodiments, the interfacial layer 203 includes an oxide of a IV or III-V group semiconductor material. In some embodiments, the interfacial layer 203 has a thickness ranging between 0.5 nm and 2 nm; and the high-k dielectric layer 204 has a thickness ranging between 1 nm and 5 nm.

Still referring to FIG. 10, PFET gate regions 208 of the CFET gate regions 108 include interfacial layers 203 directly on top and bottom surfaces of the channel layers 202, and gate dielectric layers 204 directly on top and bottom surfaces of the interfacial layers 203 and on side surfaces of the inner spacers 116. NFET gate regions 308 of the CFET gate regions 108 also include interfacial layers 203 directly on top and bottom surfaces of the channel layers 302, and a high-k (HK) dielectric layers 204 directly on top and bottom surfaces of the interfacial layers 203 and on side surfaces of the inner spacers 116 (and/or the gate spacers 111). In the depicted embodiment, the NFET gate regions 308 are vertically above the PFET gate regions such that NFETs are formed over PFETs. However, the present disclosure is not limited thereto. In other embodiments, the PFET gate regions 208 may be above the NFET gate regions 308 such that PFETs are formed over NFETs.

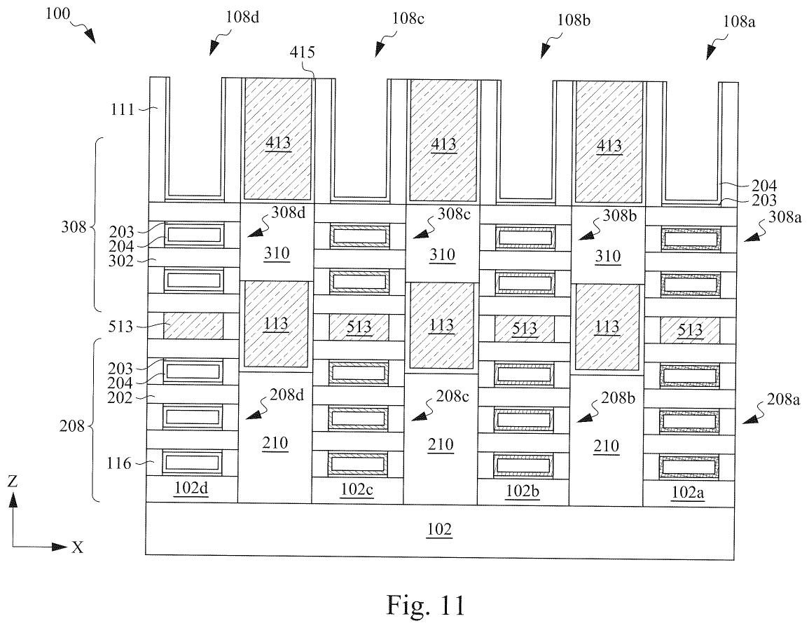

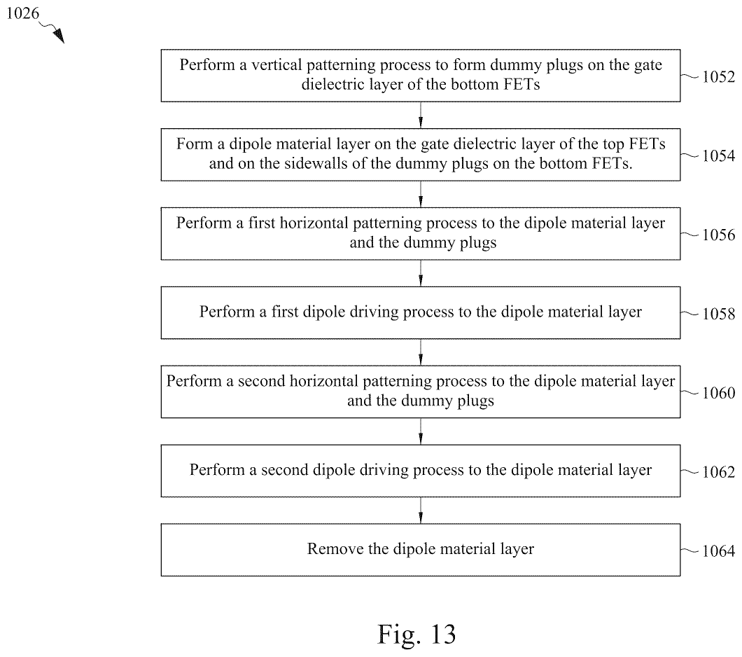

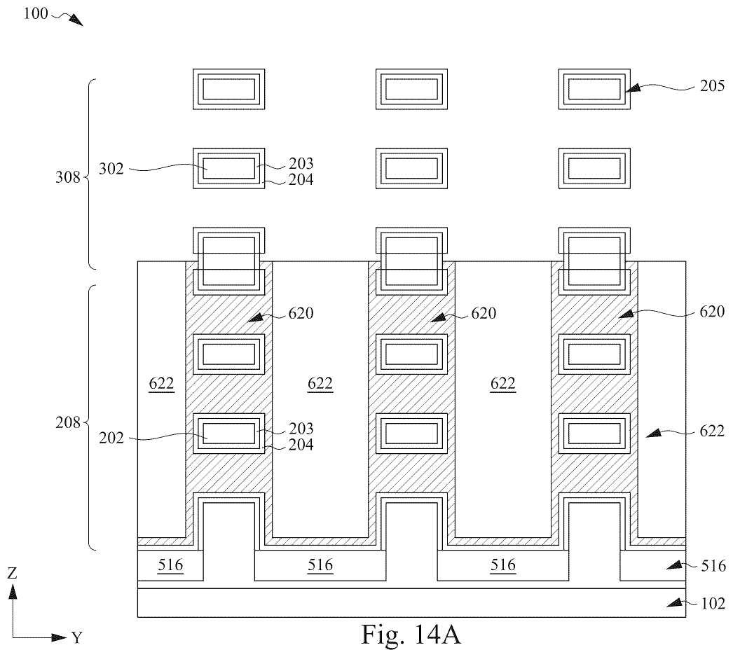

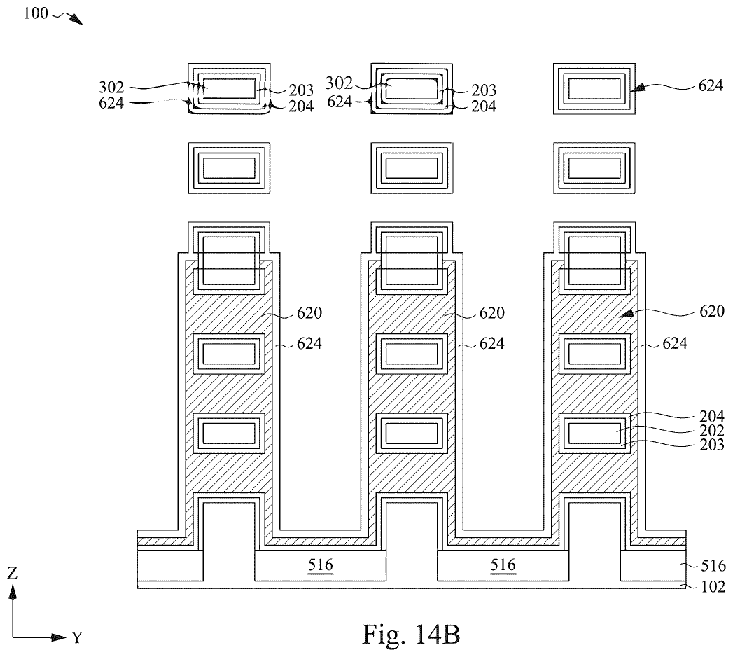

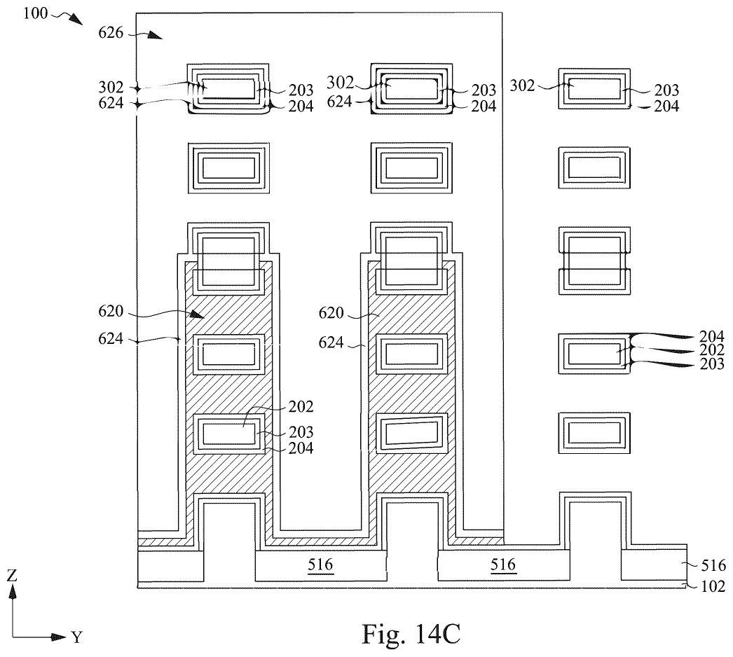

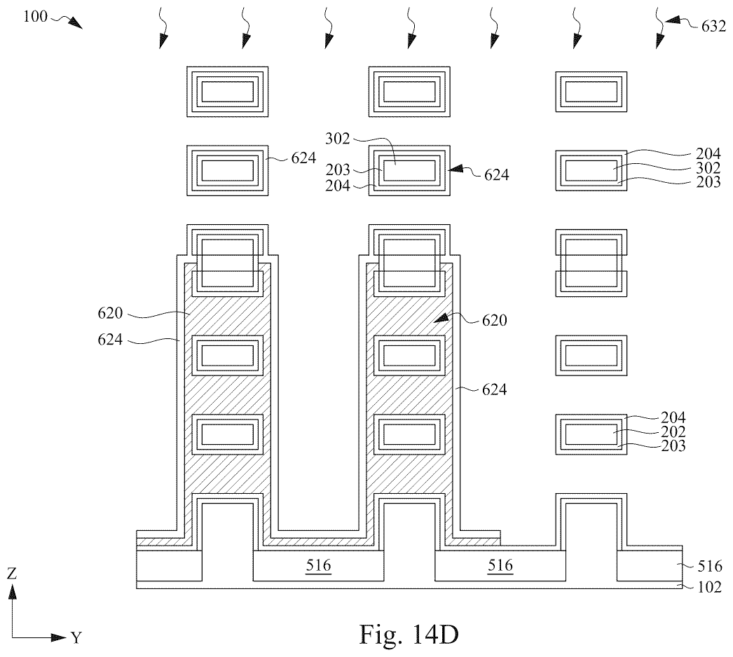

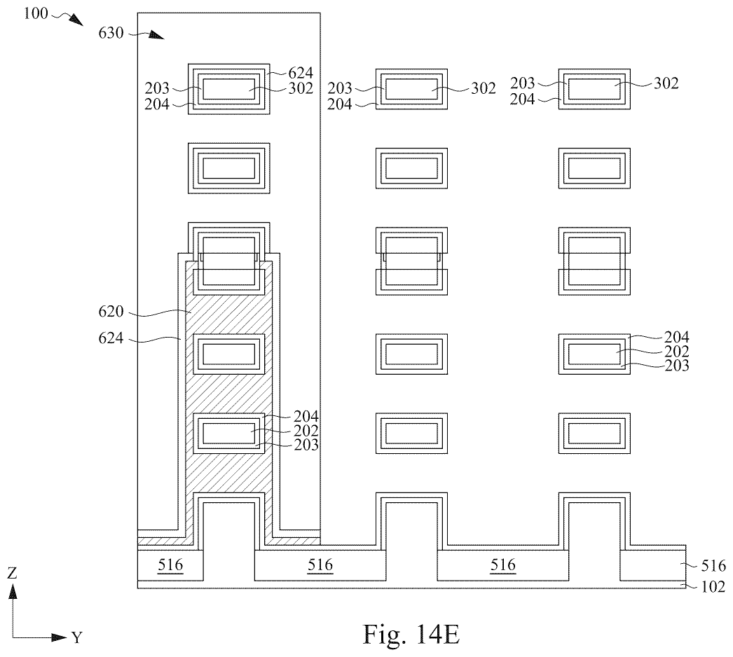

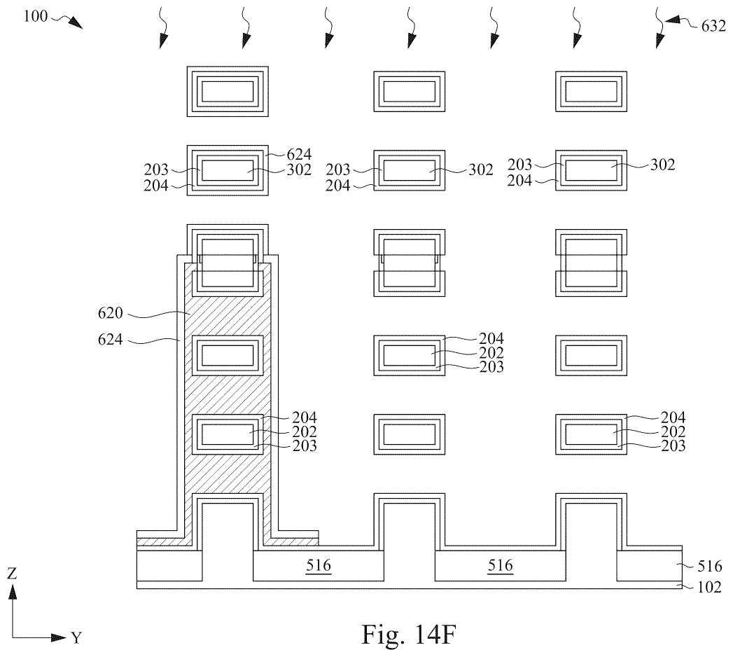

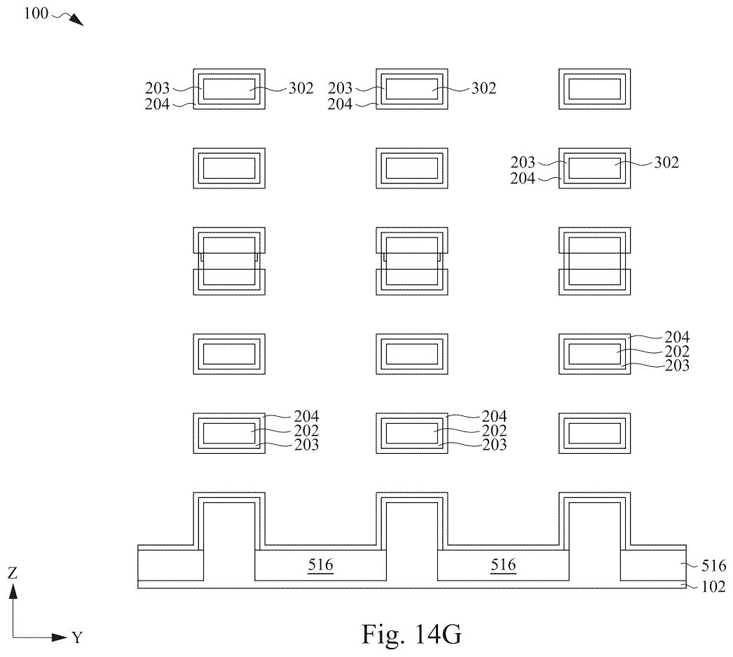

Now referring to FIG. 11, the method 1000 at operation 1026 performs a dipole treatment process to treat the gate dielectric layers 205, resulting in the gate dielectric layers with various threshold voltages. The dipole treatment process further includes multiples suboperations described below in detail with reference to FIGS. 13 and 14A through 14G. FIG. 13 is a flowchart of the method 1026 constructed according to various embodiments. FIGS. 14A through 14G are sectional views of the IC structure 100, in portion, at various fabrication stages constructed according to some embodiments. In FIGS. 14A through 14G, only three CFETs are illustrated. However, it is not intended to be limiting but for illustration. The IC structure 100 may include as many CFETs as needed in individual applications. Three CFETs include three PFETs and three NFETs stacked on the three PFETs, respectively. Each of those PFETs and NFETs has a different threshold voltage according to its design after the dipole treatment process of the method 1026. For convenience, the three CFETs in FIGS. 14A through 14G are referred to as a first CFET, a second CFET and a third CFET from left to right, respectively. More specifically, three FETs on the bottom portion are referred to as a first bottom CFET, a second bottom CFET and a third bottom CFET from left to right, respectively; and three FETs on the top portion are referred to as a first top CFET, a second top CFET and a third top CFET from left to right, respectively.

Referring to FIGS. 13 and 14A, an operation 1052 of the method 1026 includes a vertical patterning to form dummy plugs 620 on the bottom portions of the gate dielectric layer 205. Particularly, in the operation 1052, dummy plugs 620 are first formed on the top portions and the bottom portions of the gate dielectric layer 205. The dummy plugs 620 are formed by a suitable procedure, such as a procedure that includes deposition one or more dummy plug material on the gate dielectric layer 205; and performing an anisotropic etching process to remove the excessive portions of the dummy plug material such that the dummy plug material is only present and filling in the gaps between the channels. The deposition may include chemical vapor deposition (CVD), flowable CVD (CVD), low pressure CVD (LPCVD), other suitable deposition process or a combination thereof. The anisotropic etching process may include plasma etch, reactive ion etch, selective dry etch, other suitable etch, or a combination thereof. The dummy plugs 620 include one or more suitable material. In some embodiments, the dummy plugs 620 include oxide, nitride and/or carbide, such as aluminum oxide, aluminum nitride, aluminum carbide or a combination thereof. Note that the dummy plugs are designed with a composition to tune the work function of the gate dielectric layer 205, particularly the work function of the gate dielectric layer 205 in the bottom gate regions 208 during the drive-in process described later. In some embodiments, the dummy plugs 620 may include p-dipole dopants, such as aluminum (Al) oxide, vanadium (V) oxide, ruthenium (Ru) oxide, rhodium (Rh) oxide, rhenium (Re) oxide, osmium (Os) oxide, iridium (Ir), aluminum (Al) nitride, vanadium (V) nitride, ruthenium (Ru) nitride, rhodium (Rh) nitride, rhenium (Rc) nitride, osmium (Os) nitride, iridium (Ir) oxide, oxide, aluminum (Al) carbide, vanadium (V) carbide, ruthenium (Ru) carbide, rhodium (Rh) carbide, rhenium (Re) carbide, osmium (Os) carbide, iridium (Ir) carbide, or a combination thereof. The dummy plugs 620 may alternatively or additionally include other p-dipole dopants, such as titanium (Ti) oxide, zinc (Zn) oxide, indium (In) oxide, gallium (Ga) oxide, tantalum (Ta) oxide, tungsten (W) oxide, titanium (Ti) nitride, zinc (Zn) nitride, indium (In) nitride, gallium (Ga) nitride, tantalum (Ta) nitride, tungsten (W) nitride, titanium (Ti) carbide, zinc (Zn) carbide, indium (In) carbide, gallium (Ga) carbide, tantalum (Ta) carbide, tungsten (W) carbide, or a combination thereof.

Thereafter, the operation 1052 includes forming a first dummy fill (material) layer 622 to cover the bottom gate regions 208, specifically the gate dielectric layers 205 in the PFET gate regions 208. In the disclosed embodiment, a gate dielectric layer 205 further includes an interfacial layer 203 and a HK dielectric layer 204 on the interfacial layer 203, as described in FIG. 1. The first dummy fill layer 622 is a dummy structure and will be removed eventually. In some embodiments, the first dummy fill layer 622 include a bottom anti-reflective coating (BARC) material since it can be formed and removed cost-effectively. It is understood that that dummy fill material may use other suitable material. In the disclosed embodiment, the first dummy fill material layer 622 is formed by spin-on coating or other suitable technique such that it is filled to the level at the channel isolation layer 513. In another embodiment, after spin-on coating, an etching process is applied to the first dummy fill material layer 622 until it is recessed to the level at the channel isolation layer 513. The etching process includes plasma ashing or other suitable etching method according to some embodiments.

The operation 1052 further includes performing an etching process to remove the dummy plugs 620 on the top gate regions 308. The dummy plugs 620 on the top gate regions 308 are uncovered by the dummy fill layer 622, thereby being removed. The etching process may be wet etch, dry etch, other suitable etch or a combination thereof. The dry etch process may include plasma etch, reactive ion etch, selective dry etch, other suitable etch, or a combination thereof. The wet etch process may include dilute phosphoric acid, nitric acid, acetic acid, other suitable etchant or a combination thereof.

Referring to FIGS. 13 and 14B, in an operation 1054 of the method 1026, the dummy fill layer 622 is removed, and a dipole material layer 624 is formed on the gate dielectric layer 205 of the top FETs, as well as on the sidewalls of the dummy plugs 620 on the bottom FETs. The dummy fill layer 622 may be removed by any suitable method such as plasma ashing.

The dipole material layer 624 includes a dipole material includes a n-type dipole material. In furtherance of the embodiment, the dipole material layer 624 includes dipole dopant: lanthanum (La), yttrium (Y), erbium (Er), scandium (Sc), strontium (Sr), magnesium (Mg) or a combination thereof. In furtherance of the embodiment, the dipole material layer 624 includes lanthanum (La) oxide, yttrium (Y) oxide, erbium (Er), scandium (Sc) oxide, strontium (Sr) oxide, magnesium (Mg) oxide, La nitride, Y nitride, Er nitride, Sc nitride, Sr nitride, Mg nitride, La carbide, Y carbide, Er carbide, Sc carbide, Sr carbide, Mg carbide, or a combination thereof. The formation of the dipole material layer 624 includes deposition, such as CVD, LPCVD, other suitable deposition or a combination thereof. The dipole material layer 624 includes a proper thickness and proper dipole dopant concentration so that with enough dipole dopant to be introduced into the gate dielectric layer 205 during the drive-in process. In some embodiments, the dipole material layer 624 includes a thickness ranging between 0.3 nm and 2 nm.

Referring to FIGS. 13 and 14C, an operation 1056 of the method 1026 includes a first horizontal patterning process to the dipole material layer 624 so that the dipole material layer 624 and the dummy plugs 620 on the right CFET are removed. The operation 1056 includes forming a second dummy fill (material) layer 626; patterning the second dummy fill layer 626 so that the right CFET region is uncovered by the second dummy fill layer 626; removing the exposed portion of the dipole material layer 624 in the right CFET region; and removing the exposed portions of the dummy plugs 620 in the right CFET region.

The second dummy fill layer 626 is similar to the first dummy fill layer 622 in terms of composition and formation. In the disclosed embodiment, the second dummy fill layer 626 includes a BARC layer and is deposited by spin-on coating or other suitable method. The patterning the second dummy fill layer 626 includes a lithography process and etch. In some embodiments, the patterning process includes forming a patterned photoresist layer on the second dummy fill layer 626 by a lithography process that further includes coating, exposure, development, and various baking processes. The etching process to the second dummy layer 626 may include plasma ashing or other suitable method. Thereafter, the patterned photoresist layer is removed by plasma ashing or wet stripping before or after the removing the dipole material layer 624 and the dummy plugs 620. In some embodiment, a photoresist layer may be directly used as the second dummy fill layer 626. In this case, the lithography process will form a patterned dummy fill layer 626.

The etch process to remove the dipole material layer 624 includes a wet etching process. The wet etching process is applied to remove the portion of the dipole material layer 624 on the right CFET region exposed by the second dummy fill material layer 626. The etching process applied to the dipole material layer includes a wet etching process using an etchant having wet etching: hydrochloric acid (HCl) or nitric acid (HNO3) according to some embodiments.

The etch process to remove the dummy plugs 620 includes a wet etching process according to some embodiments. The wet etching process applied to the dummy plugs 620 is similar to the wet etching process applied to the plug material in the operation 1052.

Referring to FIGS. 13 and 14D, an operation 1058 of the method 1026 includes removing the second dummy fill layer 626 and performing a first driving process 628. The removing of the second dummy fill layer 626 may include a plasma ashing, other suitable etching process or a combination thereof.

The first dipole driving process is applied to drive the dipole dopants from the dipole material layer 624 into the gate dielectric layer 205 of the top FETs (NFETs in the present example). The first dipole driving process includes an annealing process at a first temperature T1. In some embodiments, the first temperature T1 is greater than 500° C., such as ranging between 500° C. and 800° C. or ranging between 550° C. and 800° C. The first driving process also introduce the different dopants from the dummy plugs 620 into the gate dielectric layer 205 of the bottom FETs (PFETs in the present example). For example, aluminum may be introduced into the gate dielectric layer 205 of the bottom FETs, thereby also tuning the work function of the gate dielectric layer and accordingly tuning the threshold voltage of the bottom FETs. As the third CFET is free of the dipole material layer 624 and the dummy plugs 620, the corresponding gate dielectric layer 205 in the third CFET region is not impacted.

Referring to FIGS. 13 and 14E, an operation 1060 of the method 1026 includes performing a second horizontal patterning process to the dipole material layer 624. The second horizontal patterning process is applied to the dipole material layer 624 so that the dipole material layer 624 and the dummy plugs 620 on the middle CFET are removed. The operation 1060 is similar to the operation 1056 and includes forming a third dummy fill layer 630; patterning the third dummy fill layer 630 so that the middle CFET region is uncovered by the third dummy fill layer 630; removing the exposed portion of the dipole material layer 624 in the middle CFET region; and removing the exposed portions of the dummy plugs 620 in the middle CFET region. Various above processes in the operation 1060 are similar to the corresponding processes in the operation 1056. Similar descriptions are not repeated herein for simplicity. After the operation 1060, the dipole material layer 624 and the dummy plugs 620 in the middle CFET region are removed.

Referring to FIGS. 13 and 14F, an operation 1062 of the method 1026 includes removing the third dummy fill layer 630 and performing a second dipole driving process 632. The removing of the third dummy fill layer 630 may include a plasma ashing, other suitable etching process or a combination thereof.

The second dipole driving process 632 is applied to drive more dipole dopants from the dipole material layer 624 into the gate dielectric layer 205 of the top FETs (NFETs in the present example). Now the second driving process impacts the left CFET but not the middle and right CFET. The second dipole driving process 632 includes an annealing process at a second temperature T2. In some embodiments, T2 is different from T1. Since the second dipole driving process 632 further tunes the left CFET to have different threshold voltages than those of the middle CFETs. In furtherance of the embodiment, T2 is less than T1. In some embodiments, the second temperature T2 is less than 500° C., such as ranging between 420° C. and 480° C. As the middle and right CFETs are free of the dipole material layer 624 and the dummy plugs 620, the corresponding gate dielectric layers 205 in the middle and right CFET regions are not impacted.

Referring to FIGS. 13 and 14G, an operation 1062 of the method 1064 includes removing the dipole material layer 624 by a suitable etching process. In some embodiments, the dipole material layer 624 is removed by a wet etching process with an etchant having hydrochloric acid (HCl) or nitric acid (HNO3).

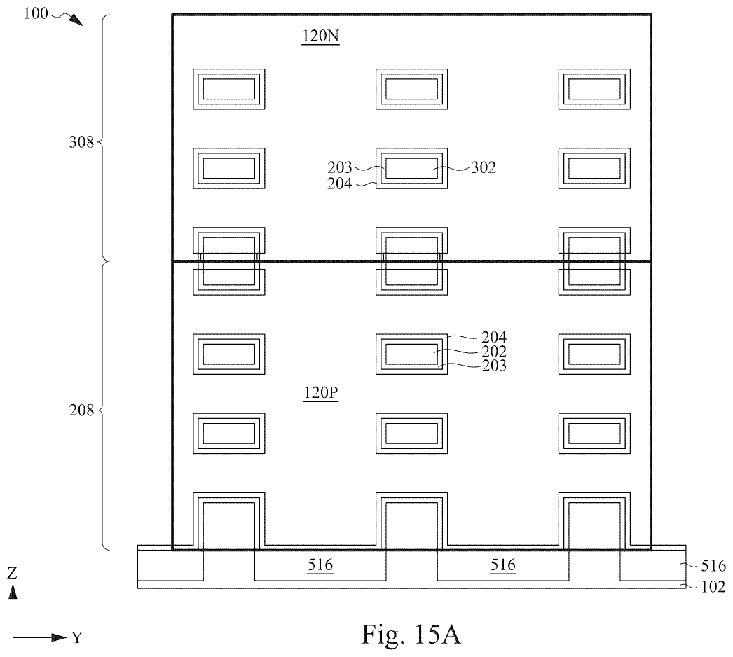

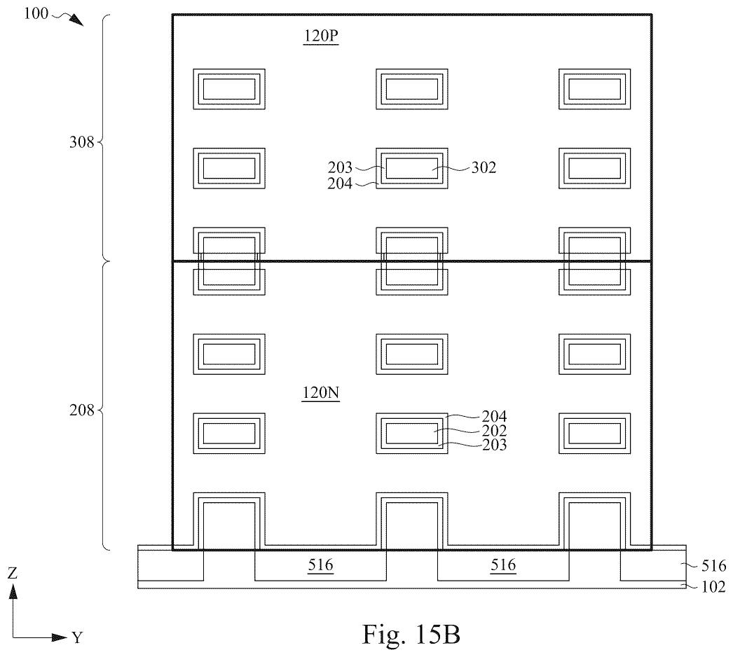

By the above dipole treatment process, the gate dielectric layer of various top FETs and bottom FETs are treated differently with different dipole compositions and different dipole dopant concentrations, thereby achieving different threshold voltages. This is further described below with reference to FIG. 15A. The left NFET is dipole treated with twice dipole driving processes and has a low threshold voltage; the middle NFET is dipole treated with one dipole driving process and has a middle threshold voltage; and the right NFET is not dipole treated and has a high threshold voltage. Similarly, the left PFET is dipole treated with twice dipole driving processes and has a low threshold voltage; the middle PFET is dipole treated with one dipole driving process and has a middle threshold voltage; and the right PFET is not dipole treated and has a high threshold voltage.

Specific threshold voltages can be tuned through tuning the dipole driving processes, such as tuning the anneal temperatures, anneal durations, and dipole compositions of the dipole material layer. In some embodiments, taking the top NFETs as example, the dipole dopant concentration in the gate dielectric layer 205 of the middle NFET is C1; and the dipole dopant concentration in the gate dielectric layer 205 of the left NFET is C2. C2 is greater than C1. C1 and C2 are measured by atomic percentage. In some embodiments, the ratio C2/C1 ranges between 1.2 and 1.8.

In some embodiments, the method 1000 may include more than two dipole driving processes. For example, the method 1000 includes a number (n) of dipole driving processes to tune a number (n) of CFETs with different threshold voltages. In this case, the operations 1056 and 1058 may be repeated n times, similar to the operations 1060 and 1062, wherein the operations 1056 and 1058 are repeated once. The number n is an integer, and may have a value such as 2, 3, 4 and etc.

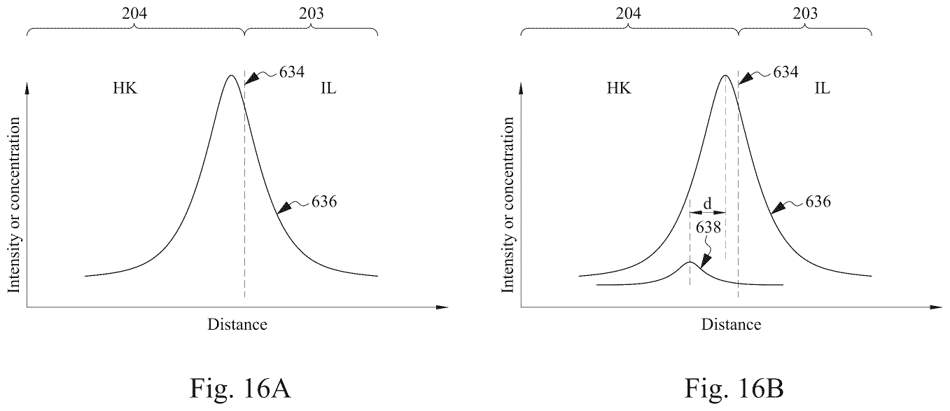

Furthermore, the dipole dopants from the dipole material layer 624 and the dummy plugs 620 are distributed in the gate dielectric layer 205 with certain distributions illustrated in FIGS. 16A and 16B. FIG. 16A illustrates the distributions of the dipole dopant from the dipole material layer 624 to the gate dielectric layer 205 in the top gate region 308. In this case, the dummy plugs 620 do not include dipole dopants. FIG. 16B illustrates the distribution of the dipole dopant from the dipole material layer 624 to the gate dielectric layer 205 in the top gate region 308 and the distribution of the dipole dopant from the dummy plugs 620 to the gate dielectric layer 205 in the bottom gate region 208. Note that the gate dielectric layer 205 includes the interfacial layer 203 on the channels and the high-k dielectric layer 204 on the interfacial layer 203. The horizontal axis shows distance from the high-k dielectric layer 204 from the interfacial layer 203 along the z direction. The vertical axis shows dipole dopant concentration (or intensity). The dashed line 634 represents the interface between the interfacial layer 203 and the high-k dielectric layer 204.

In the disclosed embodiments illustrated in FIG. 16A, the distribution 636 of the dipole dopant from the dipole material layer 624 to the gate dielectric layer 205 in the top gate region 308 has a concentration peak is located within the high-k dielectric layer 204 and close to the interface 634.

In the disclosed embodiments illustrated in FIG. 16B, the distribution 636 of the dipole dopant from the dipole material layer 624 to the gate dielectric layer 205 in the top gate region 308 has a concentration peak is located within the high-k dielectric layer 204 and close to the interface 634. The distribution 638 of the dipole dopant from the dummy plugs 620 to the gate dielectric layer 205 in the bottom gate region 208 has a concentration peak is located within the high-k dielectric layer 204 and is distanced from the peak of the distribution 636 by d further away from the interface 634. In some embodiment, d is ranging between 0.5 nm and 1.5 nm. Particularly, in the disclosed embodiment, the distribution 638 of the dipole dopant from the dummy plugs 620 to the gate dielectric layer 205 in the bottom gate region 208 has a lower concentration than that of the distribution 638 of the dipole dopant from the dummy plugs 620 to the gate dielectric layer 205 in the bottom gate region 208.

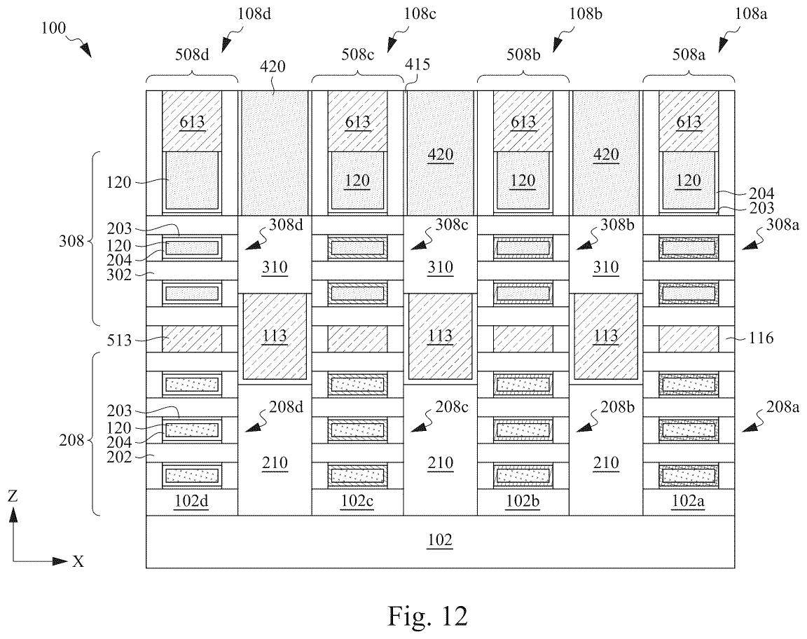

Now referring back to FIGS. 3B and 12 or 15A, at an operation 1030, a gate electrode 120 is formed on the gate dielectric layer 205, thereby forming the gate structures 508. The gate electrodes 120 include bottom portions on the bottom gate region 208 and top portions on the top gate region 208, respectively referred to as bottom gate electrodes and top gate electrodes. The top gate electrodes and bottom gate electrodes are different from each other in composition. In some embodiments, the gate electrodes 120 include a work function metal layer, a cap layer, a glue layer, and a fill metal layer. The work function metal layers are designed to tune the threshold voltages of various FETs and use different metal or metal alloys for NFETs and PFETs. The work function metal used for FETs is referred to as n-type work function metal and the work function metal used for PETs is referred to as p-type work function metal. In the present embodiments, the bottom FETs are PFETs, and the bottom gate electrodes include p-type work function metal and are referred to as p-type gate electrodes 120P; and the top FETs are NFETs, and the top gate electrodes include n-type work function metal and are referred to as n-type gate electrodes 120N, in FIG. 12. The formation of the gate electrodes 120 may include forming the p-type gate electrodes 120P on the bottom gate regions 208 and then forming the n-type gate electrodes 120N on the top gate regions 308. In some embodiments, the operation 1030 includes depositing various conductive materials of the p-type gate electrodes 120P; etching to recess the p-type gate electrodes 120P so that they are only formed on the bottom gate regions 208; depositing various conductive materials of the n-type gate electrodes 120N on the top gate regions 308; and performing a CMP process. In some embodiments, the operation 1030 further includes forming gate isolators between the n-type gate electrodes 120N on the top gate regions 308 and the p-type gate electrodes 120P so that they are only formed on the bottom gate regions 208. The gate isolators include one or more dielectric material to separate and isolate the n-type gate electrodes 120N and the p-type gate electrodes 120P. The formation of the gate isolators include deposition using a suitable method, such as CVD, LPCVD, atomic layer deposition (ALD), other suitable deposition techniques or a combination thereof.

In some embodiments, a p-type work function metal includes any suitable p-type work function metal material, such as titanium nitride (TiN), tantalum nitride (TaN), ruthenium (Ru), molybdenum (Mo), tungsten (W), platinum (Pt), titanium (Ti), aluminum (Al), tantalum carbide (TaC), tantalum carbide nitride (TaCN), tantalum silicon nitride (TaSiN), titanium silicon nitride (TiSiN), other suitable materials, or combinations thereof. In some embodiments, a n-type work function metal includes any suitable n-type work function metal material, such as tantalum (Ta), titanium aluminum (TiAl), titanium aluminum carbide (TiAlC), titanium aluminum oxide (TiAlO), titanium aluminum nitride (TiAlN) or a combination thereof.

The gate electrodes 120 may additionally include fill metal material, such as copper (Cu), tungsten (W), cobalt (Co), ruthenium (Ru), other suitable conductive materials, or combinations thereof. The metal gate structures 508 may include other material layers, such as a barrier layer, a glue layer, and/or a capping layer. The various layers of the gate electrodes 120 may be formed by any suitable method, such as CVD, ALD, PVD, plating, chemical oxidation, thermal oxidation, other suitable methods, or combinations thereof. Thereafter, the method 1000 may perform one or more polishing process (e.g., CMP) to remove any excess conductive materials and planarize the top surface of the IC structure 100.

Still referring back to FIGS. 3B and 12, the method 1000 may include other fabrication steps before, during and after the various operations described above. For example, the method 1000 includes forming self-aligned cap 613 on the gate electrode 120. The self-aligned cap 613 includes one or more dielectric material formed by a procedure that further includes selective etching to recess the gate electrodes 120; depositing one or more dielectric material; and performing a CMP process to remove the excessive portions and planarize the top surface. In another example, the method 1000 includes forming an interconnect structure that includes contacts, vias and metal lines. In furtherance of the embodiment, source/drain (S/D) contacts 420 are formed on the source/drain features by a suitable procedure that includes patterning, deposition and CMP.

In the above disclosed embodiment, CFETs include NFETs stacked over the PFETs; the dipole material layer 624 is N-type dipole material, and the dummy plugs 620 may include a P-type dipole material. With the disclosed method having vertical and horizontal patterning processes and multiple dipole-driving processes, the PFETs and NFETs are tuned with respective threshold voltages.

In an alternative embodiment as illustrated in FIG. 15B, CFETs include PFETs stacked over the NFETs; the dipole material layer 624 is P-type dipole material, and the dummy plugs 620 may include a N-type dipole material. With the disclosed method having vertical and horizontal patterning processes and multiple dipole-driving processes, the NFETs and PFETs are tuned with respective threshold voltages as well. In some embodiments, the dipole material layer 624 having P-type dipole composition includes aluminum (Al) oxide, vanadium (V) oxide, ruthenium (Ru) oxide, rhodium (Rh) oxide, rhenium (Re) oxide, osmium (Os) oxide, iridium (Ir), aluminum (Al) nitride, vanadium (V) nitride, ruthenium (Ru) nitride, rhodium (Rh) nitride, rhenium (Rc) nitride, osmium (Os) nitride, iridium (Ir) oxide, oxide, aluminum (Al) carbide, vanadium (V) carbide, ruthenium (Ru) carbide, rhodium (Rh) carbide, rhenium (Re) carbide, osmium (Os) carbide, iridium (Ir) carbide, or a combination thereof. In alternative embodiments, the dipole material layer 624 having P-type dipole composition may additionally or alternatively includes titanium (Ti) oxide, zinc (Zn) oxide, indium (In) oxide, gallium (Ga) oxide, tantalum (Ta) oxide, tungsten (W) oxide, titanium (Ti) nitride, zinc (Zn) nitride, indium (In) nitride, gallium (Ga) nitride, tantalum (Ta) nitride, tungsten (W) nitride, titanium (Ti) carbide, zinc (Zn) carbide, indium (In) carbide, gallium (Ga) carbide, tantalum (Ta) carbide, tungsten (W) carbide, or a combination thereof.

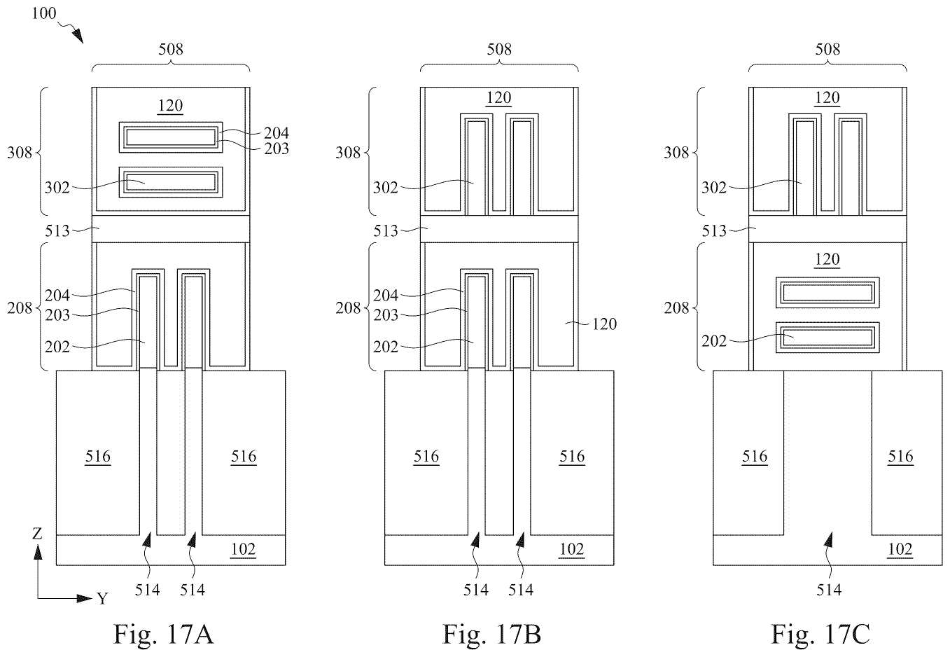

As described above, a CFET structure and the method making the same can effectively form various NFETs and PFETs with various threshold voltages through the disclosed dipole material patterning and dipole treatments. The IC structure 100 includes NFETs and PFETs vertically stacked on. The channels 302 of the NFETs and the channels 202 of the PFETs are longitudinally oriented along a horizontal direction, such as along x direction. However, the disclosed method can also be applied to form other CFET structure with various threshold voltages. In some embodiments, the channels 202 of the bottom FETs are vertically oriented and the top channels 302 of the top FETs are horizontally oriented, such as one illustrated in FIG. 17A. The threshold voltages of the bottom FETs and the threshold voltages of the top FETs are tuned differently, as those described above. In some other embodiments, the channels 202 of the bottom FETs are vertically oriented and the top channels 302 of the top FETs are vertically oriented as well, such as one illustrated in FIG. 17B. The threshold voltages of the bottom FETs and the threshold voltages of the top FETs are tuned differently, as those described above. In yet some other embodiments, the channels 202 of the bottom FETs are horizontally oriented and the top channels 302 of the top FETs are vertically oriented, such as one illustrated in FIG. 17A. The threshold voltages of the bottom FETs and the threshold voltages of the top FETs are tuned differently, as those described above.

In various embodiments of the IC structure 100 and the method 1000 making the same, the IC structure 100 includes a CFET structure formed by a monolithic method, therefore being referred to as a monolithic CFET structure, in which both NFETs and PFETs are formed on a same semiconductor substrate. Alternatively, the CFET structure may be formed by a sequential method, in which NFETs and PFETs are formed on different substrates and bonded together, therefore being referred to as sequential CFET structure. The disclosed method of dipole treatment to achieve various threshold voltages can also be used to the sequential CFET structure. The present disclosure is generally related to semiconductor devices and the fabrication thereof, and more particularly to methods of fabricating field-effect transistors (FETs), such as complimentary FETs (CFETs) and/or other FETs. Particularly, the semiconductor devices include CFETs and the method making the same. The method includes a procedure with multiple vertical and horizontal patterning processes and multiple dipole-driving processes to form CFETs with multiple threshold voltages.

Although not limiting, the present disclosure offers advantages for tuning CFET semiconductor devices to have multiple threshold voltages (Vt). One example advantage is tuning Vt without varying metal gate structure dimensions from one device to another. Instead, dipole loop processes are used to iteratively pattern and anneal dipole material layer and dummy plugs in different gate regions of the IC structure having various CFETs. Another example advantage is that PFET and NFET gate regions in a same CFET may be doped differently to have different materials and different amounts of dopants. Another example advantage is that gate regions within a same NFET or PFET of a CFET may be doped differently from channel to channel, offering different threshold activation voltages for a single NFET or PFET. Another example advantage is the flexibility to vary dopant concentration in different gate regions in a horizontal and a vertical direction of the CFET.

In one example aspect, the present disclosure provides a method of semiconductor fabrication. The method includes providing a substrate; forming active regions on the substrate, wherein field-effect transistors (FETs) with different threshold voltages are formed on the active regions, wherein the active regions include a first active region, a second active region and a third active region, and wherein FETs include first type FETs in a bottom region and second type FETs over in a top region over the bottom region, the second type FETs being opposite to the first type FETs; forming a gate dielectric layer on first channels in the bottom region and on second channels in the top region; forming dummy plugs on the gate dielectric layer in the bottom region; depositing a dipole material layer on the gate dielectric layer in the top region and on sidewalls of the dummy plugs in the bottom region; performing a first patterning process to the dipole material layer and the dummy plugs such that the dipole material layer and the dummy plugs are absent on the third active region; performing a first dipole driving process to the gate dielectric layer, thereby driving first dipole dopants from the dipole material layer into the gate dielectric layer in the top region within the first active region and the second active region; performing a second patterning process to the dipole material layer such that the dipole material layer and the dummy plugs are absent on the second active region; and performing a second dipole driving process to the gate dielectric layer, thereby further driving the first dipole dopants from the dipole material layer into the gate dielectric layer in the top region within the first active region.

Another one aspect of the present disclosure pertains to a method of semiconductor fabrication. The method includes forming active regions on a substrate, wherein field-effect transistors (FETs) with different threshold voltages are formed on the active regions, wherein the active regions include a first active region, a second active region and a third active region, and wherein FETs include first type FETs in a bottom region and second type FETs over in a top region over the bottom region, the second type FETs being opposite to the first type FETs; forming a gate dielectric layer on first channels in the bottom region and on second channels in the top region; forming dummy plugs on the gate dielectric layer; removing the dummy plugs in the top region; depositing a dipole material layer on the gate dielectric layer in the top region and on sidewalls of the dummy plugs in the bottom region; performing a first patterning process to the dipole material layer and the dummy plugs such that the dipole material layer and the dummy plugs are absent on the third active region; performing a first dipole driving process to the gate dielectric layer, thereby driving first dipole dopants from the dipole material layer into the gate dielectric layer in the top region within the first active region and the second active region; performing a second patterning process to the dipole material layer such that the dipole material layer and the dummy plugs are absent on the second active region; and performing a second dipole driving process to the gate dielectric layer, thereby further driving the first dipole dopants from the dipole material layer into the gate dielectric layer in the top region within the first active region.

Yet another aspect of the present disclosure pertains to a semiconductor structure. The semiconductor structure includes active regions formed on a substrate, wherein field-effect transistors (FETs) with different threshold voltages are formed on the active regions, wherein the active regions include a first active region and a second active region, and wherein FETs include p-type FETs in a bottom region and n-type FETs in a top region over the bottom region, and wherein the top region is over the bottom region; first channels formed on the first active region, second channels formed on the second active region, third channels formed on the first active region, and fourth channels formed on the second active region, wherein the first and second channels are in the top region and the third and fourth channels are in the bottom region; and a first gate dielectric layer disposed on the first channels, a second gate dielectric layer disposed on the second channels, a third gate dielectric layer disposed on the third channels, and a fourth gate dielectric layer disposed on the fourth channels, wherein the first gate dielectric layer includes a first dipole dopant of a first concentration, the second gate dielectric layer includes the first dipole dopant of a second concentration less than the first concentration, and the third and fourth gate dielectric layers are free of the first dipole dopant; and a first gate electrode disposed on the first gate dielectric layer, a second gate electrode disposed on the second gate dielectric layer, a third gate electrode disposed on the third gate dielectric layer, and a fourth gate electrode disposed on the fourth gate dielectric layer, wherein the first and second gate electrodes includes a n-type work function metal and the third and fourth gate electrodes includes a p-type work function metal.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method, comprising:
providing a substrate;
forming active regions on the substrate, wherein field-effect transistors (FETs) with different threshold voltages are formed on the active regions, wherein the active regions include a first active region, a second active region and a third active region, and wherein FETs include first type FETs in a bottom region and second type FETs over in a top region over the bottom region, the second type FETs being opposite to the first type FETs;
forming a gate dielectric layer on first channels in the bottom region and on second channels in the top region;
forming dummy plugs on the gate dielectric layer in the bottom region;
depositing a dipole material layer on the gate dielectric layer in the top region and on sidewalls of the dummy plugs in the bottom region;
performing a first patterning process to the dipole material layer and the dummy plugs such that the dipole material layer and the dummy plugs are absent on the third active region;
performing a first dipole driving process to the gate dielectric layer, thereby driving first dipole dopants from the dipole material layer into the gate dielectric layer in the top region within the first active region and the second active region;
performing a second patterning process to the dipole material layer such that the dipole material layer and the dummy plugs are absent on the second active region; and
performing a second dipole driving process to the gate dielectric layer, thereby further driving the first dipole dopants from the dipole material layer into the gate dielectric layer in the top region within the first active region.

2. The method of claim 1, wherein the forming of the dummy plugs includes
depositing a plug material on the gate dielectric layer in the bottom region and the top region;
applying an anisotropic etching process to remove excessive portions of the plug material such that the plug material is only present within airgaps between adjacent two of the first channels and the second channels;
forming a dummy fill layer to cover the plug material in the bottom region; and
removing the plug material in the top region and uncovered by the dummy fill layer.

3. The method of claim 2, wherein the forming of the dummy fill layer further includes
coating a bottom anti-reflective coating (BARC) layer; and
etching the BARC layer so that the BARC layer is recessed to cover the dummy plugs in the bottom region.

4. The method of claim 1, wherein the dummy plugs include Al.

5. The method of claim 1, wherein
the first type FETs are PFETs and the second type FETs are NFETs;
the dipole material layer includes a n-type dipole material; and
the dummy plugs include a p-type dipole material.

6. The method of claim 5, wherein the n-type dipole material includes lanthanum (La) oxide, yttrium (Y) oxide, erbium (Er), scandium (Sc) oxide, La nitride, Y nitride, Er nitride, Sc nitride, La carbide, Y carbide, Er carbide, Sc carbide, or a combination thereof.

7. The method of claim 6, wherein the n-type dipole material additionally includes strontium (Sr) oxide, magnesium (Mg) oxide, Sr nitride, Mg nitride, Sr carbide, Mg carbide or a combination thereof.

8. The method of claim 5, wherein
the p-type dipole material includes aluminum (Al) oxide, vanadium (V) oxide, ruthenium (Ru) oxide, rhodium (Rh) oxide, rhenium (Re) oxide, osmium (Os) oxide, iridium (Ir), aluminum (Al) nitride, vanadium (V) nitride, ruthenium (Ru) nitride, rhodium (Rh) nitride, rhenium (Re) nitride, osmium (Os) nitride, iridium (Ir) oxide, oxide, aluminum (Al) carbide, vanadium (V) carbide, ruthenium (Ru) carbide, rhodium (Rh) carbide, rhenium (Re) carbide, osmium (Os) carbide, iridium (Ir) carbide, or a combination thereof.

9. The method of claim 8, wherein the p-type dipole material additionally includes titanium (Ti) oxide, zinc (Zn) oxide, indium (In) oxide, gallium (Ga) oxide, tantalum (Ta) oxide, tungsten (W) oxide, titanium (Ti) nitride, zinc (Zn) nitride, indium (In) nitride, gallium (Ga) nitride, tantalum (Ta) nitride, tungsten (W) nitride, titanium (Ti) carbide, zinc (Zn) carbide, indium (In) carbide, gallium (Ga) carbide, tantalum (Ta) carbide, tungsten (W) carbide, or a combination thereof.

10. The method of claim 5, further comprising
forming first gate electrodes on the first type FETs; and
forming second gate electrodes on the second type FETs, wherein
the first gate electrodes include a p-type work function metal including titanium nitride (TiN), tantalum nitride (TaN), ruthenium (Ru), molybdenum (Mo), tungsten (W), platinum (Pt), titanium (Ti), aluminum (Al), tantalum carbide (TaC), tantalum carbide nitride (TaCN), tantalum silicon nitride (TaSiN), titanium silicon nitride (TiSiN), other suitable materials, or combinations thereof, and
the second gate electrodes include a n-type work function metal including tantalum (Ta), titanium aluminum (TiAl), titanium aluminum carbide (TiAlC), titanium aluminum oxide (TiAlO), titanium aluminum nitride (TiAlN) or a combination thereof.

11. The method of claim 1, wherein
the first type FETs are NFETs and the second type FETs are PFETs;
the dipole material layer includes a p-type dipole material; and
the dummy plugs include a n-type dipole material.

12. The method of claim 1, wherein the performing of first patterning process to the dipole material layer and the dummy plugs further includes
forming a dummy fill layer on the dipole material layer;
patterning the dummy fill layer to cover the first and second active regions and expose the third active region; and
etching to remove the dipole material layer and the dummy plugs on the third active region.

13. A method, comprising:
forming active regions on a substrate, wherein field-effect transistors (FETs) with different threshold voltages are formed on the active regions, wherein the active regions include a first active region, a second active region and a third active region, and wherein FETs include first type FETs in a bottom region and second type FETs over in a top region over the bottom region, the second type FETs being opposite to the first type FETs;
forming a gate dielectric layer on first channels in the bottom region and on second channels in the top region;
forming dummy plugs on the gate dielectric layer;
removing the dummy plugs in the top region;
depositing a dipole material layer on the gate dielectric layer in the top region and on sidewalls of the dummy plugs in the bottom region;
performing a first patterning process to the dipole material layer and the dummy plugs such that the dipole material layer and the dummy plugs are absent on the third active region;
performing a first dipole driving process to the gate dielectric layer, thereby driving first dipole dopants from the dipole material layer into the gate dielectric layer in the top region within the first active region and the second active region;
performing a second patterning process to the dipole material layer such that the dipole material layer and the dummy plugs are absent on the second active region; and
performing a second dipole driving process to the gate dielectric layer, thereby further driving the first dipole dopants from the dipole material layer into the gate dielectric layer in the top region within the first active region.

14. The method of claim 13, wherein
the forming of the dummy plugs further includes depositing a plug material on the gate dielectric layer in the bottom region and the top region, and applying an anisotropic etching process to remove excessive portions of the plug material such that the plug material is only present within airgaps between adjacent two of the first channels and the second channels; and
the removing of the dummy plugs in the top region further includes forming a dummy fill layer to cover the plug material in the bottom region, and etching the plug material in the top region and uncovered by the dummy fill layer.

15. The method of claim 13, wherein
the first type FETs are PFETs and the second type FETs are NFETs;
the dipole material layer includes a n-type dipole material; and
the dummy plugs include a p-type dipole material.

16. The method of claim 15, wherein
the n-type dipole material includes lanthanum (La) oxide, yttrium (Y) oxide, erbium (Er), scandium (Sc) oxide, La nitride, Y nitride, Er nitride, Sc nitride, La carbide, Y carbide, Er carbide, Sc carbide, strontium (Sr) oxide, magnesium (Mg) oxide, Sr nitride, Mg nitride, Sr carbide, Mg carbide or a combination thereof; and
the p-type dipole material includes aluminum (Al) oxide, vanadium (V) oxide, ruthenium (Ru) oxide, rhodium (Rh) oxide, rhenium (Re) oxide, osmium (Os) oxide, iridium (Ir), aluminum (Al) nitride, vanadium (V) nitride, ruthenium (Ru) nitride, rhodium (Rh) nitride, rhenium (Re) nitride, osmium (Os) nitride, iridium (Ir) oxide, oxide, aluminum (Al) carbide, vanadium (V) carbide, ruthenium (Ru) carbide, rhodium (Rh) carbide, rhenium (Re) carbide, osmium (Os) carbide, iridium (Ir) carbide, titanium (Ti) oxide, zinc (Zn) oxide, indium (In) oxide, gallium (Ga) oxide, tantalum (Ta) oxide, tungsten (W) oxide, titanium (Ti) nitride, zinc (Zn) nitride, indium (In) nitride, gallium (Ga) nitride, tantalum (Ta) nitride, tungsten (W) nitride, titanium (Ti) carbide, zinc (Zn) carbide, indium (In) carbide, gallium (Ga) carbide, tantalum (Ta) carbide, tungsten (W) carbide, or a combination thereof.

17. The method of claim 13, further comprising
forming first gate electrodes on the first type FETs; and
forming second gate electrodes on the second type FETs, wherein
the first gate electrodes include a p-type work function metal including titanium nitride (TiN), tantalum nitride (TaN), ruthenium (Ru), molybdenum (Mo), tungsten (W), platinum (Pt), titanium (Ti), aluminum (Al), tantalum carbide (TaC), tantalum carbide nitride (TaCN), tantalum silicon nitride (TaSiN), titanium silicon nitride (TiSiN), other suitable materials, or combinations thereof, and
the second gate electrodes include a n-type work function metal including tantalum (Ta), titanium aluminum (TiAl), titanium aluminum carbide (TiAlC), titanium aluminum oxide (TiAlO), titanium aluminum nitride (TiAlN) or a combination thereof.

18. A semiconductor structure, comprising:
active regions formed on a substrate, wherein field-effect transistors (FETs) with different threshold voltages are formed on the active regions, wherein the active regions include a first active region and a second active region, and wherein FETs include p-type FETs in a bottom region and n-type FETs in a top region over the bottom region, and wherein the top region is over the bottom region;
first channels formed on the first active region, second channels formed on the second active region, third channels formed on the first active region, and fourth channels formed on the second active region, wherein the first and second channels are in the top region and the third and fourth channels are in the bottom region; and
a first gate dielectric layer disposed on the first channels, a second gate dielectric layer disposed on the second channels, a third gate dielectric layer disposed on the third channels, and a fourth gate dielectric layer disposed on the fourth channels, wherein the first gate dielectric layer includes a first dipole dopant of a first concentration, the second gate dielectric layer includes the first dipole dopant of a second concentration less than the first concentration, and the third and fourth gate dielectric layers are free of the first dipole dopant; and
a first gate electrode disposed on the first gate dielectric layer, a second gate electrode disposed on the second gate dielectric layer, a third gate electrode disposed on the third gate dielectric layer, and a fourth gate electrode disposed on the fourth gate dielectric layer, wherein the first and second gate electrodes includes a n-type work function metal and the third and fourth gate electrodes includes a p-type work function metal.

19. The semiconductor structure of claim 18, wherein the first dipole dopant is a n-type dopant, and wherein
the n-type dopant includes lanthanum (La) oxide, yttrium (Y) oxide, erbium (Er), scandium (Sc) oxide, La nitride, Y nitride, Er nitride, Sc nitride, La carbide, Y carbide, Er carbide, Sc carbide, strontium (Sr) oxide, magnesium (Mg) oxide, Sr nitride, Mg nitride, Sr carbide, Mg carbide or a combination thereof.

20. The semiconductor structure of claim 19, wherein
the third gate dielectric layer includes a second dipole dopant of a third concentration, the fourth gate dielectric layer includes the second dipole dopant of a fourth concentration less than the third concentration, and the first and second gate dielectric layers are free of the second dipole dopant; and
the second dipole dopant is a p-type dipole dopant including aluminum (Al) oxide, vanadium (V) oxide, ruthenium (Ru) oxide, rhodium (Rh) oxide, rhenium (Re) oxide, osmium (Os) oxide, iridium (Ir), aluminum (Al) nitride, vanadium (V) nitride, ruthenium (Ru) nitride, rhodium (Rh) nitride, rhenium (Re) nitride, osmium (Os) nitride, iridium (Ir) oxide, oxide, aluminum (Al) carbide, vanadium (V) carbide, ruthenium (Ru) carbide, rhodium (Rh) carbide, rhenium (Re) carbide, osmium (Os) carbide, iridium (Ir) carbide, titanium (Ti) oxide, zinc (Zn) oxide, indium (In) oxide, gallium (Ga) oxide, tantalum (Ta) oxide, tungsten (W) oxide, titanium (Ti) nitride, zinc (Zn) nitride, indium (In) nitride, gallium (Ga) nitride, tantalum (Ta) nitride, tungsten (W) nitride, titanium (Ti) carbide, zinc (Zn) carbide, indium (In) carbide, gallium (Ga) carbide, tantalum (Ta) carbide, tungsten (W) carbide, or a combination thereof.
